(19) United States
(12) Patent Application Publication
(10) Pub. No.: US 2026/0180278 A1
(43) Pub. Date: Jun. 25, 2026

(54) OPTICAL DEVICE AND OPTICAL SYSTEM

(71) Applicant: TDK Corporation, Tokyo (JP)

(72) Inventors: Tetsuya SHIBATA, Tokyo (JP); Tsuyoshi KOMAKI, Tokyo (JP); Tomohito MIZUNO, Tokyo (JP); Hideaki FUKUZAWA, Tokyo (JP)

(73) Assignee: TDK Corporation, Tokyo (JP)

(21) Appl. No.: 19/421,920

(22) Filed: Dec. 16, 2025

(30) Foreign Application Priority Data
Dec. 23, 2024 (JP) 2024-226413

(51) Int. Cl. H01S 5/00; H01S 5/026; H01S 5/40

(52) U.S. Cl. CPC H01S 5/0085; H01S 5/0264; H01S 5/4087

(57) ABSTRACT

Provided are an optical device and an optical system that can appropriately irradiate a magnetic element with reflected light from an irradiated object with a simple configuration without the need for highly accurate optical axis adjustment. An optical device 1A of one aspect includes at least one magnetic element 30 having a first ferromagnetic layer, a second ferromagnetic layer, and a spacer layer sandwiched between the first and second ferromagnetic layers, laser diodes 11, 12, 13, and 14 that emit laser light, and a waveguide 20. The waveguide 20 has at least one optical input port 21i, 22i, 23i, and 24i through which the laser light from the laser diodes 11, 12, 13, and 14 is incident, and an optical output port 27o through which the light is emitted to the outside, and at least one magnetic element 30 is disposed in the vicinity of the optical output port 27o.

### CROSS-REFERENCE TO RELATED APPLICATION

This application claims a priority, under the Paris Convention, to Japanese Patent Application No. 2024-226413 filed on Dec. 23, 2024, the entirety of which is incorporated herein by reference.

### TECHNICAL FIELD

The present disclosure relates to an optical device and an optical system.

### BACKGROUND

Laser light is widely used in various fields such as industry, medicine, and communications. In particular, laser diodes that emit laser light are packaged and sold commercially, and can packages and butterfly packages are known as typical package forms.

In recent years, XR glasses such as AR (Augmented Reality) glasses and VR (Virtual Reality) glasses are expected to be as small size wearable devices. In XR glasses, it is important to miniaturize each component so that it fits into the size of a normal pair of glasses. Under these circumstances, attention is being paid to small planar lightwave circuits (PLCs) using laser diodes. It is also expected that an optical modulator having an optical waveguide formed in a material having an electro-optical effect will be used, and in particular, that an optical modulator having an optical modulation element using a lithium niobate film will be used.

Japanese Patent Application Publication No. 2022-155468 discloses an optical device having an optical modulation element preferably using a lithium niobate film and multiple laser diodes. The optical modulation element has a waveguide and multiple magnetic elements. The multiple laser diodes include a near-infrared laser used for eye tracking purposes. Near-infrared light emitted by the near-infrared laser is incident on an optical input port at one end of the waveguide, propagates through the waveguide, and is emitted to the outside from an optical output port at the other end of the waveguide, and is irradiated to the irradiated object. A portion of the reflected light reflected by the irradiated object returns from the optical output port back into the waveguide and reaches the magnetic element through a monitoring waveguide connected to the waveguide. The magnetic element measures the intensity of the reflected light returning through the monitoring waveguide, thereby detecting the state of the eyeball as the irradiated object (pupil position, gaze point, etc.).

In the optical device disclosed in Japanese Patent Application Publication No. 2022-155468, in order to return the reflected light from the irradiated object into the waveguide, it is necessary to perform optical axis adjustment (waveguide coupling) between the optical axis of the reflected light and the optical axis of the optical output port of the waveguide. However, as recognized by the present inventors, this optical axis adjustment requires highly accurate adjustment of the angle and position of the optical axis, so that there is a problem that it is not easy to properly return the reflected light into the waveguide. Furthermore, as also recognized by the present inventors, there is also a problem that a sufficient amount of light is not irradiated onto the magnetic element to measure the intensity of the reflected light because propagation loss occurs in the waveguide and monitoring waveguide, thereby reducing the intensity of the reflected light.

### SUMMARY

One aspect of the present disclosure provides an optical device comprising: at least one magnetic element having a first ferromagnetic layer, a second ferromagnetic layer, and a spacer layer sandwiched between the first ferromagnetic layer and the second ferromagnetic layer; a laser diode that emits laser light; and a waveguide, wherein the waveguide has at least one optical input port through which the laser light of the laser diode is incident and an optical output port through which the laser light is emitted to the outside, and wherein the at least one magnetic element is disposed in the vicinity of the optical output port.

One aspect of the present disclosure provides an optical system comprising the above optical device, and an optical assembly that guides the laser light emitted by the optical device to an irradiated object.

### BRIEF DESCRIPTION OF DRAWINGS

FIG. 1 is a schematic plan view of an optical device in a first embodiment of the present disclosure.

FIG. 2 is a cross-sectional view taken along line A-A in FIG. 1.

FIG. 3 is a perspective view showing the vicinity of the magnetic element in FIG. 1.

FIG. 4 is a plan view showing the vicinity of the magnetic element in FIG. 1.

FIG. 5 is a cross-sectional view taken along line B-B in FIG. 1.

FIG. 6 is a cross-sectional view taken along line C-C in FIG. 1.

FIG. 7 is a partially enlarged view of the periphery of the magnetic element in FIG. 5.

FIG. 8 is a cross-sectional view showing a magnetic element of the optical device in the first embodiment of the present disclosure.

FIG. 9 is a diagram for explaining a first mechanism of operation of the magnetic element of the optical device in the first embodiment of the present disclosure.

FIG. 10 is a diagram for explaining a second mechanism of operation of the magnetic element of the optical device in the first embodiment of the present disclosure.

FIG. 11 is a perspective view showing the vicinity of the magnetic element of the optical device in the second embodiment of the present disclosure.

FIG. 12 is a plan view showing the vicinity of the magnetic element of FIG. 11.

FIG. 13 is a cross-sectional view showing the vicinity of the magnetic element of FIG. 11.

FIG. 14 is a perspective view showing the vicinity of a magnetic element of an optical device in a third embodiment of the present disclosure.

FIG. 15 is a plan view showing the vicinity of the magnetic element of FIG. 14.

FIG. 16 is a cross-sectional view showing the vicinity of the magnetic element of FIG. 14.

FIG. 17 is a perspective view showing the vicinity of a magnetic element of an optical device in a fourth embodiment of the present disclosure.

FIG. 18 is a cross-sectional view showing the vicinity of the magnetic element in FIG. 17.

FIG. 19 is a perspective view showing the vicinity of a magnetic element of an optical device in a fifth embodiment of the present disclosure.

FIG. 20 is a cross-sectional view showing the vicinity of the magnetic element in FIG. 19.

FIG. 21 is a schematic plan view of an optical device in a sixth embodiment of the present disclosure.

FIG. 22 is a schematic plan view of the optical modulation section in FIG. 21.

FIG. 23 is a conceptual diagram of an optical system according to the present disclosure.

FIG. 24 is a schematic plan view of an optical device in a derived example of the present disclosure.

### DETAILED DESCRIPTION

One aspect of the present disclosure provides an optical device and an optical system that can appropriately irradiate a magnetic element with reflected light from an irradiated object with a simple configuration without the need for highly accurate optical axis adjustment.

Hereinafter, one embodiment of the present disclosure will be described in detail with reference to the drawings as appropriate. The drawings used in the following description may show characteristic parts in an enlarged scale for the sake of clarity, and the dimensions and ratios of each component may differ from the actual dimensions. The materials, dimensions, etc. exemplified in the following description are merely examples. The present disclosure is not limited to these examples, and can be modified as appropriate within the scope of the effects of the present disclosure. In addition, the symbol “˜” indicating a numerical range means any numerical value within the range including the numerical values written before and after it as the lower and upper limits.

### First Embodiment

Hereinafter, the first embodiment of the present disclosure will be described.

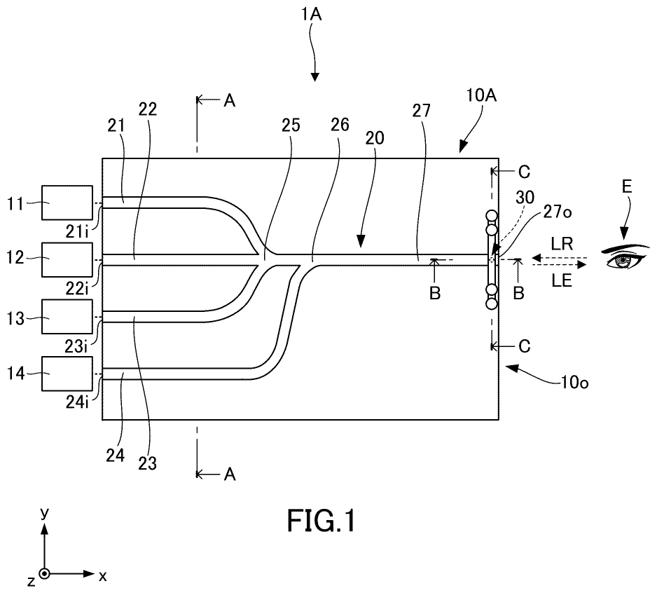

First, the configuration of an optical device 1A in the first embodiment of the present disclosure will be described with reference to FIG. 1. FIG. 1 is a schematic plan view of an optical device 1A in the first embodiment.

The optical device 1A shown in FIG. 1 has multiple laser diodes 11, 12, 13, and 14, an optical waveguide element 10A, and a magnetic element 30.

In this specification, in an xyz orthogonal coordinate system set in the figure, the direction along one side of the optical waveguide element 10A is the x direction, the direction perpendicular to the x direction is the y direction, and the direction perpendicular to the x and y directions is the z direction. The x direction is the longitudinal direction of the optical waveguide element 10A. The y direction is the width direction of the optical waveguide element 10A. The z direction is the direction perpendicular to the main surface of the optical waveguide element 10A. In the following, the directions are expressed as “positive z direction” and “negative z direction”, etc., taking into consideration the direction, and in particular the “positive z direction” may be referred to as the upward direction and the “negative z direction” referred to as the downward direction. Here, it should be noted that the z direction, which is the vertical direction, does not necessarily coincide with the direction in which gravity acts.

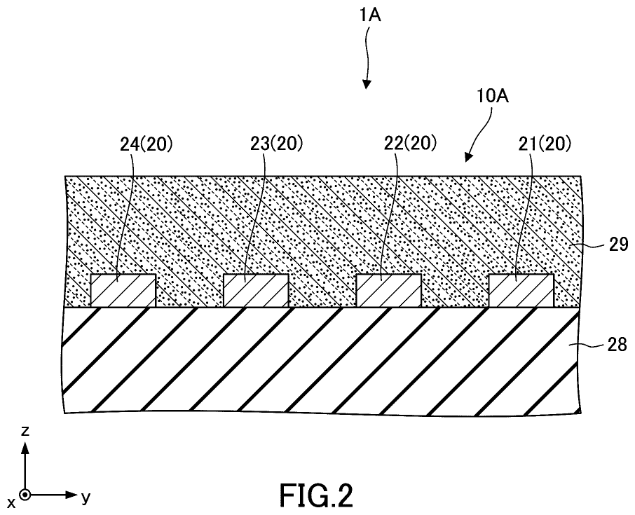

The laser diodes 11, 12, 13, and 14 are configured to emit laser light in different wavelength ranges, for example. The laser diodes 11, 12, 13, and 14 may be provided as an integrated light source module. The laser diodes 11, 12, 13, and 14 may be mounted on the upper surface of the subcarrier, for example, in the form of bare chips. In this case, the subcarrier and the substrate 28 (see, for example, FIG. 2) of the optical waveguide element 10A are joined via a metal joining layer or the like, so that the laser diodes 11, 12, 13, and 14 can be fixed to the optical waveguide element 10A.

The laser diode 11 is, for example, a red laser light source that emits laser light (red light) in a wavelength range of 590 nm˜800 nm. The laser diode 12 is, for example, a green laser light source that emits light (green light) in a wavelength range of 490 nm or more and less than 590 nm. The laser diode 13 is a blue laser light source that emits light (blue light) in a wavelength range of, for example, 380 nm or more and less than 490 nm. The laser diode 14 is a near-infrared laser light source that emits laser light (near-infrared light) in a wavelength range of, for example, 780 nm˜2500 nm. The arrangement order and number of the laser diodes 11, 12, 13, and 14 that emit light in each wavelength range are not particularly limited.

The laser diodes 11, 12, and 13 emit visible light of the three primary colors (red, green, and blue). By superimposing these emitted lights based on the principle of additive color mixing, a desired color can be expressed. The laser diodes 11, 12, and 13 may also emit light of colors other than the three primary colors.

Visible light is used, for example, for image display purposes. In order to express a desired color by superimposing the lights of each color, it is desirable to appropriately adjust the intensity of the light of each color. For example, the intensity of the emitted light from the laser diodes 11, 12, and 13 may be appropriately controlled. Alternatively, as described in the sixth embodiment described later, an optical modulation section may be provided in the optical waveguide element 10A, and optical modulation may be performed within the optical waveguide element 10A.

The laser diode 14 emits near-infrared light. Near-infrared light is used, for example, for eye tracking.

The optical waveguide element 10A is formed with a waveguide 20 that propagates light. As shown in FIG. 1, the waveguide 20 is composed of, for example, input waveguides 21, 22, 23, and 24, a first multiplexing section 25, a second multiplexing section 26, and an output waveguide 27.

The ends of the input waveguides 21, 22, 23, and 24 are formed with optical input ports 21i, 22i, 23i, and 24i for the laser light emitted by the laser diodes 11, 12, 13, and 14. The optical input ports 21i, 22i, 23i, and 24i serve as input ports for laser light, respectively. The input waveguides 21, 22, 23, and 24 are optically connected to the laser diodes 11, 12, 13, and 14, respectively. The optical axes of the laser light emitted by the laser diodes 11, 12, 13, and 14 are adjusted so that they are appropriately incident on the corresponding optical input ports 21i, 22i, 23i, and 24i.

The input waveguides 21, 22, and 23 are joined at a first multiplexing section 25 and connected to an output waveguide 27. The laser light incident on the optical input ports 21i, 22i, and 23i propagates through the input waveguides 21, 22, and 23, respectively, and is multiplexed at the first multiplexing section 25. Here, the input waveguides 21, 22, and 23 are configured to be multiplexed at the first multiplexing section 25, but multiplexing sections may be provided in multiple stages, and for example, the input waveguides 21 and 22 may be multiplexed, and then the input waveguide 23 may be multiplexed.

The light multiplexed at the first multiplexing section 25 propagates through the output waveguide 27 and is emitted to the outside as output light LE from the optical output port 27o formed at the end of the output waveguide 27. The optical output port 27o serves as an output port for laser light. The optical output port 27o is provided on one side of the optical waveguide element 10A. In this specification, one side of the optical waveguide element 10A on which the optical output port 27o is provided is referred to as the optical output surface 10o.

The input waveguide 24 is connected to the output waveguide 27 through the second multiplexing section 26. The laser light incident on the optical input port 24i from the laser diode 14 propagates through the input waveguide 24 and propagates through the output waveguide 27 via the second multiplexing section 26. The light propagating through the output waveguide 27 is emitted to the outside as output light LE from the optical output port 27o formed at the end of the output waveguide 27. The near-infrared light propagating through the input waveguide 24 may be multiplexed with the visible light propagating through the input waveguides 21, 22, and 23 in the second multiplexing section 26.

The emitted light LE emitted from the optical output port 27o reaches the irradiated object E, with the optical path controlled by, for example, a MEMS mirror. The irradiated object E is, for example, a human eye. The emitted light LE is reflected by the irradiated object E. The reflected light LR reflected by the irradiated object E travels in the opposite direction along the same optical path as the emitted light LE, and returns to the vicinity of the optical output port 27o. The reflected light LR is irradiated to the optical output surface 10o, including the vicinity of the optical output port 27o. FIG. 1 shows a schematic diagram of the emitted light LE, the reflected light LR, and the irradiated object E.

As shown in FIG. 1, the magnetic element 30 is disposed in the vicinity of the optical output port 27o of the optical waveguide element 10A. The reflected light LR is irradiated to the magnetic element 30 disposed in the vicinity of the optical output port 27o. This allows the magnetic element 30 to receive the reflected light LR, thereby making it possible to measure the intensity of the reflected light LR.

The magnetic element 30 is used, for example, in eye tracking, and functions as an optical sensor that detects the intensity of near-infrared light. The near-infrared light emitted by the laser diode 14 propagates through the waveguide 20 via the optical input port 24i and is emitted as output light LE from the optical output port 27o. In eye tracking, the gaze direction can be detected by irradiating the human eye with near-infrared light and measuring the intensity of the reflected light LR (corneal reflected light). The gaze direction may be detected with higher accuracy by combining the measurement results of the intensity of the reflected light LR with the measurement results of other sensors, etc.

With reference to FIG. 2, a cross section of the optical waveguide element 10A of the optical device 1A in the first embodiment will be described. FIG. 2 is a cross section taken along line A-A in FIG. 1.

As shown in FIG. 2, in the optical waveguide element 10A of the optical device 1A, a waveguide 20 is formed on a substrate 28. The waveguide 20 and the upper surface of the substrate 28 may be in contact with each other or may be spaced apart from each other. The waveguide 20 may be formed, for example, in a layer disposed on the substrate 28. Here, the waveguide 20 is provided so as to protrude from the upper surface of the substrate 28 in the positive z direction. However, the shape of the waveguide 20 and the method of forming the waveguide 20 are not particularly limited.

The waveguide 20 is covered with a clad 29. FIG. 2 shows the cross sections of the input waveguides 21, 22, 23, and 24, but the other waveguides 20 are also formed on the substrate 28 and covered with the clad 29.

From the viewpoint of confining light in the waveguide 20 and improving the light propagation efficiency, it is advantageous to use a material having a lower refractive index than the material of the waveguide 20 for the material of the substrate 28. For example, a material containing aluminum oxide, particularly sapphire, can be used as the material of the substrate 28.

It is advantageous to use a material having a higher refractive index than the substrate 28 for the material of the layer in which the waveguide 20 is formed. In addition, a material having an electro-optic effect can be used as the material of the layer in which the waveguide 20 is formed, for example, a material containing lithium niobate can be used as the main component.

The material of the clad 29 can be appropriately selected in combination with the materials of the waveguide 20 and the substrate 28. It is advantageous that the clad 29 is made of a material having a lower refractive index than the waveguide 20 and having optical transparency. The clad 29 may be made of, for example, SiO₂, Al₂O₃, MgF₂, La₂O₃, ZnO, HfO₂, MgO, Y₂O₃, CaF₂, In₂O₃, or a mixture thereof. The materials of the waveguide 20, the substrate 28, and the clad 29 are not limited to the above examples.

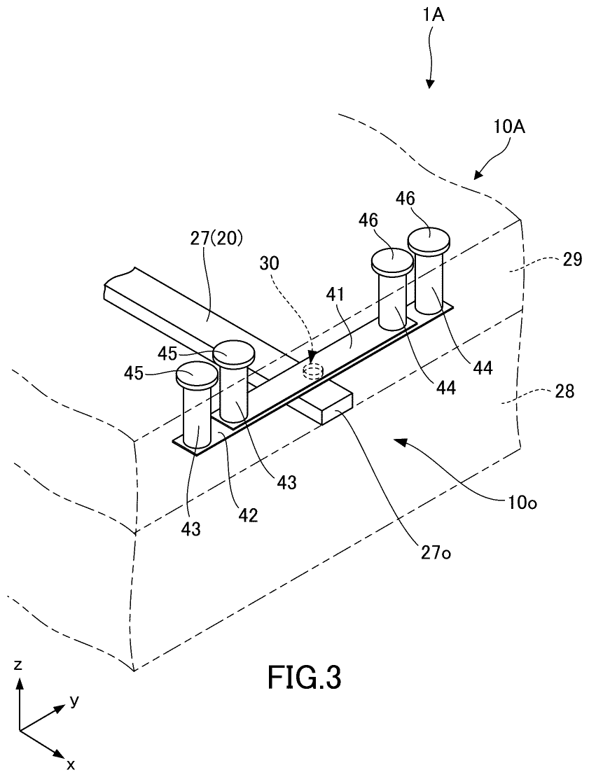

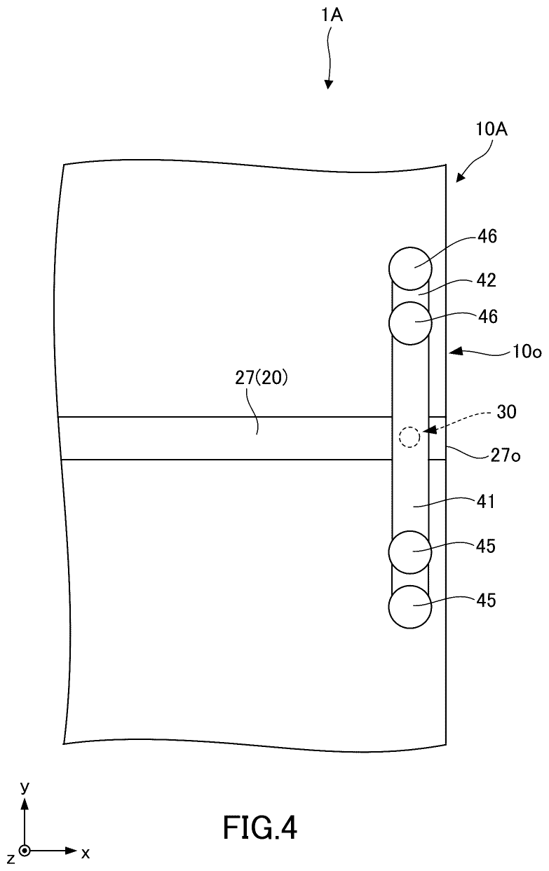

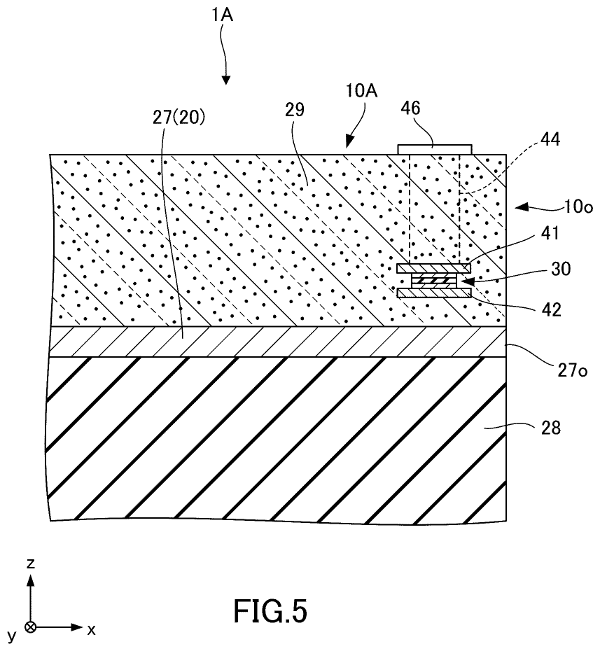

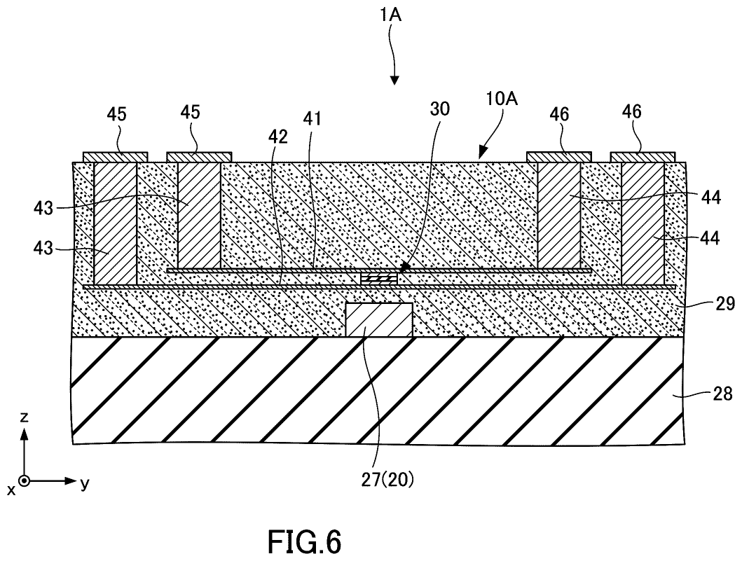

The magnetic element 30 of the optical device 1A in the first embodiment will be described with reference to FIG. 3 to FIG. 6. FIG. 3 is a perspective view showing the vicinity of the magnetic element 30 in FIG. 1. FIG. 4 is a plan view showing the vicinity of the magnetic element 30 in FIG. 1. FIG. 5 is a cross-sectional view taken along line B-B in FIG. 1. FIG. 5 shows a cross section of the magnetic element 30 in the zx plane. FIG. 6 is a cross-sectional view taken along line C-C in FIG. 1. FIG. 6 shows a cross section of the magnetic element 30 in the yz plane.

As shown in FIG. 3 to FIG. 6, the magnetic element 30 is disposed near the optical output port 27o of the optical waveguide element 10A. The magnetic element 30 is disposed above the substrate 28. Here, the magnetic element 30 is disposed in the clad 29 that covers the waveguide 20, and the magnetic element 30 is embedded in the optical waveguide element 10A so that it cannot be separated.

Although not shown, the optical device 1A may have a magnetic element 30 at a position other than the vicinity of the optical output port 27o of the optical waveguide element 10A. That is, the optical device 1A may have a plurality of magnetic elements, and at least one of the plurality of magnetic elements, the magnetic element 30, is disposed in the vicinity of the optical output port 27o. The other magnetic elements may be used for other purposes, such as white balance adjustment of visible light.

As shown in FIG. 3 to FIG. 6, the magnetic element 30 is disposed at a position offset from the waveguide 20. More specifically, the magnetic element 30 is disposed at a position different in height direction or width direction from the waveguide 20 so that the light propagating through the waveguide 20 is not irradiated onto the magnetic element 30. It is advantageous that the magnetic element 30 is disposed at a position spaced apart from the waveguide 20 so that the light leaking from the waveguide 20 does not reach the magnetic element 30.

As shown in FIG. 3 to FIG. 6, the magnetic element 30 is electrically connected to an upper electrode 41, a lower electrode 42, via wirings 43, 44, an input terminal 45, and an output terminal 46.

The upper electrode 41 and the lower electrode 42 include a material having electrical conductivity. The upper electrode 41 and the lower electrode 42 are made of, for example, a plate-shaped member including a material having electrical conductivity, and are disposed opposite to each other with the magnetic element 30 sandwiched between upper electrode 41 and the lower electrode 42. The upper electrode 41 is connected to a first surface of the magnetic element 30. The lower electrode 42 is connected to a second surface of the magnetic element 30. Hereinafter, the first surface of the magnetic element 30 located on the upper electrode 41 side may be referred to as the upper surface, and the second surface of the magnetic element 30 located on the lower electrode 42 side may be referred to as the lower surface. The upper and lower surfaces of the magnetic element 30 face each other in the stacking direction of the magnetic element 30.

As the material of the upper electrode 41 and the lower electrode 42, for example, metals such as Cu, Al, Au, or Ru can be used. Ta or Ti may be stacked above and below these metals. In addition, as the upper electrode 41 and the lower electrode 42, a stacked film of Cu and Ta, a stacked film of Ta, Cu, and Ti, a stacked film of Ta, Cu, and TaN, or TiN or TaN may be used.

The upper electrode 41 and the lower electrode 42 may be optically transparent to the wavelength range of light irradiated to the magnetic element 30. For example, the upper electrode 41 and the lower electrode 42 may be transparent electrodes containing oxide transparent electrode materials such as indium tin oxide (ITO), indium zinc oxide (IZO), zinc oxide (ZnO), and indium gallium zinc oxide (IGZO). The upper electrode 41 and the lower electrode 42 may be configured to have a plurality of columnar metals in these transparent electrode materials.

The via wiring 43 connects the input terminal 45 to the upper electrode 41 or the lower electrode 42. The input terminal 45 is provided corresponding to the via wiring 43. Here, as an example, two via wirings 43 and two input terminals 45 are provided. One of the input terminals 45 is electrically connected to the upper electrode 41 to allow a current or voltage is input therein. The other of the input terminals 45 is electrically connected to the lower electrode 42, and is connected to a reference potential. The input terminal 45 is exposed, for example, on the upper surface of the clad 29.

The via wiring 44 connects the output terminal 46 to the upper electrode 41 or the lower electrode 42. The output terminal 46 is provided corresponding to the via wiring 44. Here, as an example, two via wirings 44 and two output terminals 46 are provided. One of the output terminals 46 is electrically connected to the upper electrode 41, and an electrical signal is output. The other of the output terminals 46 is electrically connected to the lower electrode 42, and is connected to a reference potential. The output terminal 46 is exposed, for example, on the upper surface of the clad 29.

The via wirings 43, 44, the input terminal 45, and the output terminal 46 include a material having electrical conductivity. The materials of the via wirings 43, 44, the input terminal 45, and the output terminal 46 can be the same as those of the upper electrode 41 and the lower electrode 42 exemplified above.

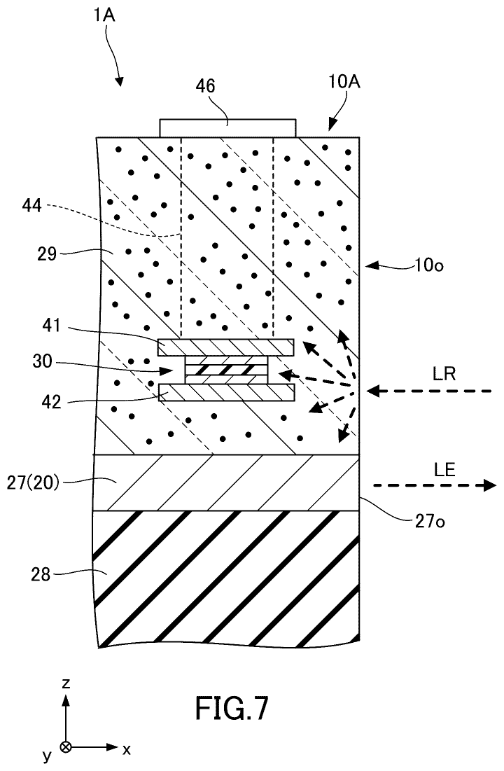

With reference to FIG. 7, the operation of irradiating the reflected light LR to the magnetic element 30 of the optical device 1A will be described hereinafter. FIG. 7 is a partially enlarged view of the periphery of the magnetic element 30 in FIG. 5. FIG. 7 shows the operation of irradiating the reflected light LR to the magnetic element 30.

As shown in FIG. 7, the magnetic element 30 is disposed in the vicinity of the optical output port 27o. The magnetic element 30 is disposed so as to be embedded in the clad 29, and is spaced apart from the upper surface of the output waveguide 27.

The near-infrared light emitted by the laser diode 14 is emitted to the outside as the emitted light LE from the optical output port 27o. The emitted light LE is reflected by the human eye, which is the irradiated object E, and travels in the opposite direction along the same optical path as the emitted light LE, and is irradiated to the optical output surface 10o on which the optical output port 27o is formed. In FIG. 7, the emitted light LE is emitted from the optical output port 27o in the positive x direction, and the reflected light LR is irradiated to the optical output surface 10o in the negative x direction.

The reflected light LR irradiated to the optical output surface 10o propagates while diffusing within the clad 29. At least a portion of the reflected light LR reaches the magnetic element 30 arranged within the clad 29 and is irradiated to the magnetic element 30. At least a portion of the reflected light LR is irradiated to the magnetic element 30 from a direction intersecting the stacking direction of the magnetic element 30. Specifically, at least a portion of the reflected light LR is irradiated to the magnetic element 30 from a direction perpendicular to the stacking direction. The magnetic element 30 outputs an electrical signal according to the intensity of the irradiated reflected light LR, thereby making it possible to measure the intensity of the reflected light LR.

In the above-mentioned conventional technology, it is necessary to appropriately adjust the direction and position of the reflected light LR so that a sufficient amount of reflected light LR is incident on the optical output port 27o of the output waveguide 27. However, there is a problem that this optical axis adjustment is not easy. Furthermore, in the conventional technology, the reflected light LR needs to propagate through the waveguide 20 (the output waveguide 27 and the monitoring waveguide connected to the output waveguide 27). However, there is also a problem that the reflected light LR is not irradiated with sufficient intensity to the magnetic element 30 due to the propagation loss of the output waveguide 27 and the monitoring waveguide.

In contrast, in the optical device 1A in the first embodiment, it is sufficient to irradiate the reflected light LR to the optical output surface 10o located around the optical output port 27o. The magnetic element 30 is arranged at a position to receive the reflected light LR propagating outside the waveguide 20. The reflected light LR irradiated to the optical output surface 10o propagates through the clad 29 without passing through the output waveguide 27, and is irradiated to the magnetic element 30. With this configuration, there is no need to perform highly accurate optical axis adjustment (waveguide coupling) to make the reflected light LR incident on the optical output port 27o, and there is no need to provide a monitoring waveguide. Furthermore, the reflected light LR reaches the magnetic element 30 arranged in the vicinity of the optical output port 27o without propagating through the waveguide 20. This makes it possible to prevent propagation loss in the waveguide 20, and to allow a sufficient amount of reflected light LR to be irradiated to the magnetic element 30.

Here, it should be noted that the vicinity of the optical output port 27o where the magnetic element 30 is disposed means that the distance between the magnetic element 30 and the optical output port 27o is less than a predetermined distance. The distance between the magnetic element 30 and the optical output port 27o may be set so that the magnetic element 30 can sufficiently measure the intensity of the reflected light LR.

For example, the distance between the magnetic element 30 and the optical output port 27o may be set so as to be equal to or less than the distance of 10 wavelengths of near-infrared light. Specifically, the wavelength range of near-infrared light is 780 nm˜2500 nm, and for example, the distance between the magnetic element 30 and the optical output port 27o may be set to 25 m or less (less than the distance of 10 wavelengths of a wavelength of 2500 nm). Also, for example, the distance between the magnetic element 30 and the optical output port 27o may be set so that the magnetic element 30 is irradiated with 10% or more of the light energy of the reflected light LR incident on the optical output surface 10o. By setting as described above, a sufficient amount of reflected light LR can be irradiated to the magnetic element 30. Here, it should be noted these specific values are merely examples. The distance between the magnetic element 30 and the optical output port 27o may be further increased depending on the near-infrared light transmittance of the clad 29 and the near-infrared light sensitivity of the magnetic element 30.

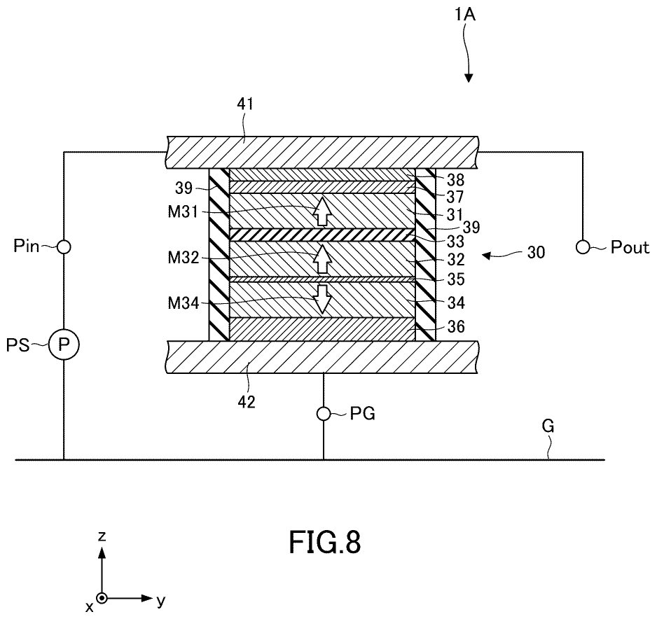

The configuration of the magnetic element 30 will be described with reference to FIG. 8. FIG. 8 is a cross-sectional view showing the magnetic element 30 of the optical device 1A in the first embodiment. In FIG. 8, the magnetizations M31, M32, and M34 in the state (initial state) of the first ferromagnetic layer 31, the second ferromagnetic layer 32, and the third ferromagnetic layer 34 are indicated by arrows.

As shown in FIG. 8, the magnetic element 30 has at least a first ferromagnetic layer 31, a second ferromagnetic layer 32, and a spacer layer 33. In FIG. 8, the second ferromagnetic layer 32, the spacer layer 33, and the first ferromagnetic layer 31 are stacked in this order toward the positive z direction to form a stacked body. The upper surface of the spacer layer 33 is in contact with the lower surface of the first ferromagnetic layer 31. The lower surface of the spacer layer 33 is in contact with the upper surface of the second ferromagnetic layer 32. In this specification, the stacking direction of the magnetic element 30 means the stacking direction of the second ferromagnetic layer 32, the spacer layer 33, and the first ferromagnetic layer 31. In FIG. 8, the stacking direction of the magnetic element 30 coincides with the z direction.

The magnetic element 30 is, for example, an MTJ (Magnetic Tunnel Junction) element. The first ferromagnetic layer 31 and the second ferromagnetic layer 32 are made of a ferromagnetic material, and the spacer layer 33 is made of an insulating material. In the magnetic element 30, the resistance value when a current is passed in the stacking direction changes in response to the relative change between the state of magnetization M31 of the first ferromagnetic layer 31 and the state of magnetization M32 of the second ferromagnetic layer 32. Such an element is also called a magnetoresistance effect element.

The stacked body that constitutes the magnetic element 30 includes a third ferromagnetic layer 34, a magnetic coupling layer 35, an underlayer 36, a perpendicular magnetization inducing layer 37, a cap layer 38, and a sidewall insulating layer 39, and may further include other layers as necessary. The maximum width of the magnetic element 30 in a plan view from the stacking direction is, for example, 10 nm˜2000 nm.

The first ferromagnetic layer 31 is a light detection layer in which the state of magnetization M31 changes when light is irradiated from the outside. The first ferromagnetic layer 31 is also called a magnetization free layer. The magnetization free layer is a layer including a magnetic material whose magnetization state changes when external energy is applied. The external energy applied to the first ferromagnetic layer 31 is, for example, light irradiated from the outside, a current flowing in the stacking direction of the magnetic element 30, an external magnetic field, etc. The state of magnetization M31 of the first ferromagnetic layer 31 changes depending on the intensity of the light irradiated to the first ferromagnetic layer 31.

The first ferromagnetic layer 31 includes a ferromagnetic material. The first ferromagnetic layer 31 includes at least one of magnetic elements such as Co, Fe, or Ni. The first ferromagnetic layer 31 may include a non-magnetic element such as B, Mg, Hf, or Gd in addition to the magnetic elements as described above. The first ferromagnetic layer 31 may be, for example, an alloy including a magnetic element and a non-magnetic element. The first ferromagnetic layer 31 may be composed of a plurality of layers. The first ferromagnetic layer 31 may be, for example, a CoFeB alloy, a laminate in which a CoFeB alloy layer is sandwiched between Fe layers, or a laminate in which a CoFeB alloy layer is sandwiched between CoFe layers.

The first ferromagnetic layer 31 may be an in-plane magnetized film having an easy axis of magnetization in the in-plane direction, or a perpendicular magnetized film having an easy axis of magnetization in the direction perpendicular to the plane of the film. The in-plane direction is parallel to the xy plane, and the direction perpendicular to the plane of the film is the z direction.

The film thickness of the first ferromagnetic layer 31 is, for example, 1.0 nm˜5.0 nm, with 1.0 nm˜2.0 nm as an example. When the first ferromagnetic layer 31 is a perpendicular magnetized film, if the film thickness of the first ferromagnetic layer 31 is thin, the perpendicular magnetic anisotropy becomes stronger due to the interface effect with the layers above and below the first ferromagnetic layer 31. As a result, the perpendicular magnetic anisotropy of the first ferromagnetic layer 31 becomes stronger, and the force of the magnetization M31 of the first ferromagnetic layer 31 returning to the direction perpendicular to the film surface (initial state) becomes stronger. On the other hand, if the film thickness of the first ferromagnetic layer 31 is thick, the interface effect between the layers above and below the first ferromagnetic layer 31 becomes relatively weak. As a result, the perpendicular magnetic anisotropy of the first ferromagnetic layer 31 becomes weak.

When the film thickness of the first ferromagnetic layer 31 becomes thinner, the volume as a ferromagnetic body becomes smaller, and when the film thickness becomes thicker, the volume as a ferromagnetic body becomes larger. The reactivity of the magnetization M31 of the first ferromagnetic layer 31 when external energy is applied is inversely proportional to the product (KuV) of the magnetic anisotropy (Ku) and the volume (V) of the first ferromagnetic layer 31. In other words, when the product of the magnetic anisotropy and the volume of the first ferromagnetic layer 31 becomes smaller, the reactivity to light becomes higher. From this viewpoint, in order to enhance the response to light, it is advantageous to appropriately design the magnetic anisotropy of the first ferromagnetic layer 31 and then reduce the volume of the first ferromagnetic layer 31.

If the thickness of the first ferromagnetic layer 31 is thicker than 2.0 nm, an insertion layer made of, for example, Mo or W may be provided in the first ferromagnetic layer 31. For example, the first ferromagnetic layer 31 may be a laminate in which a ferromagnetic layer, an insertion layer, and a ferromagnetic layer are stacked in this order. The interfacial magnetic anisotropy at the interface between the insertion layer and the ferromagnetic layer enhances the perpendicular magnetic anisotropy of the entire first ferromagnetic layer 31. The thickness of the insertion layer is, for example, 0.1 nm˜0.6 nm.

The second ferromagnetic layer 32 is a magnetization fixed layer. The magnetization fixed layer is a layer made of a magnetic material in which the state of magnetization M32 is less likely to change than the magnetization free layer when external energy is applied.

When external energy is applied, the direction and strength of magnetization M32 of the second ferromagnetic layer 32, which is a magnetization fixed layer, is less likely to change than that of the first ferromagnetic layer 31, which is a magnetization free layer. The coercive force of the second ferromagnetic layer 32 is, for example, greater than that of the first ferromagnetic layer 31. The second ferromagnetic layer 32 has an easy axis of magnetization in the same direction as the first ferromagnetic layer 31, for example. The second ferromagnetic layer 32 may be an in-plane magnetized film or a perpendicular magnetized film.

The second ferromagnetic layer 32 may be made of a material similar to that of the first ferromagnetic layer 31, for example. The second ferromagnetic layer 32 may be a laminate in which, for example, Co with a thickness of 0.4 nm˜1.0 nm, Mo with a thickness of 0.1 nm 0.5 nm, a CoFeB alloy with a thickness of 0.3 nm˜1.0 nm, and Fe with a thickness of 0.3 nm 1.0 nm are laminated in this order.

The magnetization M32 of the second ferromagnetic layer 32 may be fixed by magnetic coupling with the third ferromagnetic layer 34 via the magnetic coupling layer 35. In this case, the combination of the second ferromagnetic layer 32, the magnetic coupling layer 35, and the third ferromagnetic layer 34 may be referred to as a magnetization fixed layer.

The third ferromagnetic layer 34 is magnetically coupled with the second ferromagnetic layer 32, for example. The magnetic coupling is, for example, an antiferromagnetic coupling, and occurs due to RKKY interaction. The material constituting the third ferromagnetic layer 34 may be the same as that of the first ferromagnetic layer 31, for example. The magnetic coupling layer 35 may be made of a material such as Ru or Ir.

The spacer layer 33 is a non-magnetic layer disposed between the first ferromagnetic layer 31 and the second ferromagnetic layer 32. The spacer layer 33 is sandwiched between the first ferromagnetic layer 31 and the second ferromagnetic layer 32. The spacer layer 33 is composed of a layer made of a conductor, an insulator, or a semiconductor, or a layer containing a current-carrying point made of a conductor in an insulator. The thickness of the spacer layer 33 can be adjusted depending on the orientation direction of the magnetization M31 of the first ferromagnetic layer 31 and the magnetization M32 of the second ferromagnetic layer 32 in the initial state described later.

For example, when the spacer layer 33 is made of an insulating material, the magnetic element 30 has a magnetic tunnel junction consisting of the first ferromagnetic layer 31, the spacer layer 33, and the second ferromagnetic layer 32. Such an element is called an MTJ element. In this case, the magnetic element 30 can exhibit the TMR (Tunnel Magnetoresistance) effect. When the spacer layer 33 is made of a non-magnetic conductive material, the magnetic element 30 can exhibit the GMR (Giant Magnetoresistance) effect. Such an element is called a GMR element. The magnetic element 30 may be called an MTJ element, a GMR element, etc., depending on the material of the spacer layer 33, but is also collectively called a magnetoresistance effect element.

When the spacer layer 33 is made of an insulating material, the spacer layer 33 can be made of a material containing aluminum oxide, magnesium oxide, titanium oxide, silicon oxide, etc. The spacer layer 33 may contain elements such as Al, B, Si, Mg, or magnetic elements such as Co, Fe, Ni, in addition to these insulating materials. By adjusting the thickness of the spacer layer 33 so that a high TMR effect is generated between the first ferromagnetic layer 31 and the second ferromagnetic layer 32, a high magnetoresistance change rate can be obtained. In order to efficiently generate the TMR effect, the thickness of the spacer layer 33 may be about 0.5 nm˜5.0 nm, or even about 1.0 nm˜2.5 nm.

When the spacer layer 33 is made of a nonmagnetic conductive material, a conductive material such as Cu, Ag, Au, or Ru can be used for the spacer layer 33. In order to efficiently generate the GMR effect, the thickness of the spacer layer 33 may be about 0.5 nm 5.0 nm, or even about 2.0 nm˜3.0 nm.

When the spacer layer 33 is made of a nonmagnetic semiconductor material, metal materials such as zinc oxide, indium oxide, tin oxide, germanium oxide, gallium oxide, or ITO can be used for the spacer layer 33. In this case, the thickness of the spacer layer 33 may be about 1.0 nm˜4.0 nm.

When a layer including a current-carrying point formed by a conductor in a nonmagnetic insulator is used as the spacer layer 33, a structure including a current-carrying point formed by a nonmagnetic conductor such as Cu, Au, or Al in a nonmagnetic insulator formed by aluminum oxide or magnesium oxide may be used. The conductor may also be formed by a magnetic element such as Co, Fe, or Ni. In this case, the film thickness of the spacer layer 33 may be about 1.0 nm˜2.5 nm. The current-carrying point may be, for example, a columnar body. The diameter of the columnar body when viewed from a direction perpendicular to the film surface may be 1.0 nm˜5.0 nm.

The underlayer 36 is disposed between the third ferromagnetic layer 34 and the lower electrode 42. The underlayer 36 is a seed layer or a buffer layer. The seed layer is a layer that enhances the crystallinity of a layer stacked on the seed layer. The seed layer includes, for example, Pt, Ru, Hf, Zr, or NiFeCr. The seed layer has a thickness of, for example, 1.0 nm˜5.0 nm. The buffer layer is a layer that relieves lattice mismatch between different crystals. The buffer layer contains, for example, Ta, Ti, W, Zr, Hf, or nitrides of these elements. The buffer layer has a thickness of, for example, 1.0 nm˜5.0 nm.

The cap layer 38 is provided between the first ferromagnetic layer 31 and the upper electrode 41. The cap layer 38 prevents damage to the lower layer during the process and improves the crystallinity of the lower layer during annealing. The cap layer 38 has a thickness of, for example, 3.0 nm or less so that the first ferromagnetic layer 31 is irradiated with sufficient light. The cap layer 38 is, for example, MgO, W, Mo, Ru, Ta, Cu, Cr, or a laminated film of these.

The perpendicular magnetization inducing layer 37 is formed when the first ferromagnetic layer 31 is a perpendicular magnetization film. The perpendicular magnetization inducing layer 37 is laminated on the first ferromagnetic layer 31. The perpendicular magnetization inducing layer 37 induces perpendicular magnetic anisotropy in the first ferromagnetic layer 31. The perpendicular magnetization inducing layer 37 is, for example, magnesium oxide, W, Ta, Mo, etc. When the perpendicular magnetization inducing layer 37 is magnesium oxide, it is advantageous that the magnesium oxide has oxygen deficiency in order to increase the conductivity. The film thickness of the perpendicular magnetization inducing layer 37 is, for example, 0.5 nm˜2.0 nm.

The sidewall insulating layer 39 covers the periphery of the laminate including the first ferromagnetic layer 31 and the second ferromagnetic layer 32. The sidewall insulating layer 39 is, for example, an oxide, nitride, or oxynitride of Si, Al, or Mg.

A method for manufacturing the magnetic element 30 will be described hereinafter. The magnetic element 30 can be manufactured by a lamination process of each layer, an annealing process, and a processing process.

A part of the clad 29 is laminated on the substrate 28 on which the waveguide 20 is formed, and the lower electrode 42 is placed on top of it. Next, the underlayer 36, the third ferromagnetic layer 34, the magnetic coupling layer 35, the second ferromagnetic layer 32, the spacer layer 33, the first ferromagnetic layer 31, the perpendicular magnetization inducing layer 37, and the cap layer 38 are laminated in this order on the lower electrode 42. Each layer is formed by, for example, sputtering.

Then, the film laminated as described above is annealed. The annealing temperature is, for example, 250° C.˜450° C. After that, the laminated film is processed into a predetermined columnar body by photolithography and etching. The columnar body may be a cylinder or a rectangular column. For example, the shortest width of the columnar body when viewed from the stacking direction may be 10 nm˜2000 nm, or 30 nm˜500 nm.

Then, an insulating layer is formed so as to cover the side surface of the columnar body. The insulating layer becomes a sidewall insulating layer 39. The sidewall insulating layers 39 may be laminated multiple times. Next, the upper surface of the cap layer 38 is exposed from the sidewall insulating layer 39 by CMP (chemical mechanical polishing), and the upper electrode 41 is formed on the cap layer 38.

The above process makes it possible to manufacture the magnetic element 30. The magnetic element 30 does not need to be bonded to the base material by an adhesive layer or the like, so that the magnetic element 30 can be manufactured regardless of the material that constitutes the base. The magnetic element 30 can be manufactured by the same process as the process for forming the waveguide 20 on the substrate 28. For example, the waveguide 20 and the magnetic element 30 can be formed on the same substrate 28 by a vacuum film-forming process or the like. In addition, by further laminating the clad 29 so as to cover the periphery of the sidewall insulating layer 39, the magnetic element 30 is disposed so as to be embedded in the clad 29.

FIG. 8 schematically shows the magnetic element 30, as well as an upper electrode 41 in contact with the upper surface of the magnetic element 30, a lower electrode 42 in contact with the lower surface of the magnetic element 30, and a circuit connected to the upper electrode 41 and the lower electrode 42.

The upper electrode 41 is connected to, for example, an input terminal Pin and an output terminal Pout, and the lower electrode 42 is connected to, for example, a reference potential terminal PG. The input terminal Pin corresponds to one of the input terminals 45 electrically connected to the upper electrode 41. The output terminal Pout is electrically connected to the upper electrode 41 and corresponds to one of the output terminals 46. The reference potential terminal PG corresponds to the other of the input terminals 45 and the other of the output terminals 46 electrically connected to the lower electrode 42. The reference potential terminal PG is connected to a reference potential. The reference potential may be provided outside the optical device 1A. The reference potential may be ground G or may be something other than ground G.

The magnetic element 30 converts the change in the state of the irradiated light into an electrical signal and outputs it. More specifically, the output voltage or output current of the electrical signal output from the magnetic element 30 changes depending on the intensity of the irradiated light.

The input terminal Pin is connected to the power supply PS. The power supply PS may be a current source or a voltage source. The power supply PS may be mounted on the optical device 1A or may be provided outside the optical device 1A.

When the input terminal Pin is connected to the power supply PS as a current source, the output terminal Pout outputs the resistance value of the magnetic element 30 in the stacking direction as a voltage. When the input terminal Pin is connected to the power supply PS as a voltage source, the output terminal Pout outputs the resistance value of the magnetic element 30 in the stacking direction as a current. When it is not necessary to apply a current or voltage to the magnetic element 30 from the outside, the input terminal Pin and the power supply PS do not need to be provided.

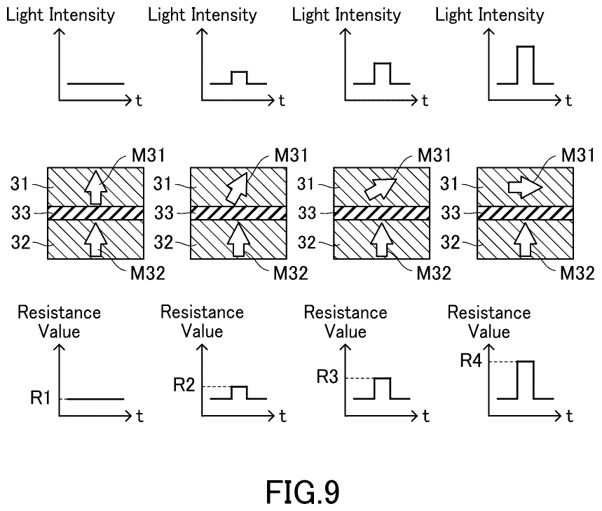

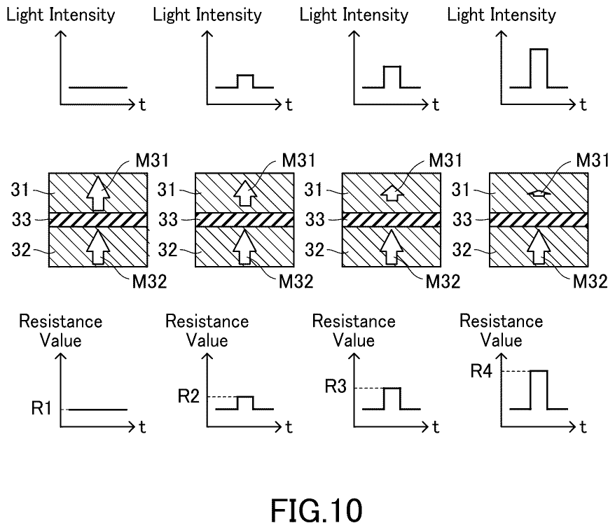

The mechanism by which the magnetic element 30 operates as an optical sensor will be described with reference to FIG. 9 and FIG. 10. FIG. 9 is a diagram for explaining a first mechanism of operation of the magnetic element 30 of the optical device 1A in the first embodiment. FIG. 10 is a diagram for explaining a second mechanism of operation of the magnetic element 30 of the optical device 1A in the first embodiment. In the upper graphs of FIG. 9 and FIG. 10, the vertical axis represents the intensity of light irradiated to the first ferromagnetic layer 31, and the horizontal axis represents time. In the middle graphs of FIG. 9 and FIG. 10, the first ferromagnetic layer 31, the second ferromagnetic layer 32, and the spacer layer 33 are illustrated. In the lower graph of FIG. 10, the vertical axis represents the resistance value in the stacking direction of the magnetic element 30, and the horizontal axis represents time.

It is known that the output voltage or output current of the electric signal output from the magnetic element 30 changes depending on the intensity of the irradiated light. The exact mechanism by which the output voltage or output current of the electrical signal output from the magnetic element 30 changes depending on the intensity of the irradiated light has not yet been clarified, but for example, the following two mechanisms are considered. The first mechanism is that the direction of magnetization changes depending on the intensity of the light irradiated to the magnetic element 30. The second mechanism is that the magnitude of magnetization changes depending on the intensity of the light irradiated to the magnetic element 30.

With reference to FIG. 9, the first mechanism of operation related to the magnetic element 30 of the optical device 1A in the first embodiment will be explained.

In a state where the first ferromagnetic layer 31 is irradiated with light of a first intensity (hereinafter referred to as the initial state), the magnetization M31 of the first ferromagnetic layer 31 and the magnetization M32 of the second ferromagnetic layer 32 are parallel to each other. At this time, the resistance value in the stacking direction of the magnetic element 30 indicates a first resistance value R1, and the magnitude of the output voltage or output current from the magnetic element 30 indicates a first value. The first intensity may be a state where the first ferromagnetic layer 31 is not irradiated with light (i.e., the intensity of the light is zero).

For example, when a constant current (sense current) is passed in the stacking direction of the magnetic element 30, a voltage is generated at both ends of the magnetic element 30 in the stacking direction. The resistance value in the stacking direction of the magnetic element 30 can be calculated from the voltage value using Ohm's law. The output voltage from the magnetic element 30 is generated between the upper electrode 41 and the lower electrode 42.

In the example shown in FIG. 9, it is advantageous to pass the sense current from the first ferromagnetic layer 31 to the second ferromagnetic layer 32. By passing the sense current from the first ferromagnetic layer 31 to the second ferromagnetic layer 32, a spin transfer torque in the same direction as the magnetization M32 of the second ferromagnetic layer 32 acts on the magnetization M31 of the first ferromagnetic layer 31. As a result, the magnetization M31 of the first ferromagnetic layer 31 and the magnetization M32 of the second ferromagnetic layer 32 are parallel to each other in the initial state. In addition, by passing the sense current from the first ferromagnetic layer 31 to the second ferromagnetic layer 32, it is possible to prevent the magnetization M31 of the first ferromagnetic layer 31 from being reversed during operation.

When the intensity of the light irradiated to the magnetic element 30 changes, the external energy applied to the first ferromagnetic layer 31 changes. As a result, the direction of the magnetization M31 of the first ferromagnetic layer 31 is tilted with respect to the initial state. The angle between the magnetization M31 of the first ferromagnetic layer 31 in the initial state and the magnetization M31 of the first ferromagnetic layer 31 in the light irradiated state is greater than 0° and less than 90°.

When the magnetization M31 of the first ferromagnetic layer 31 tilts from the initial state, the resistance value in the stacking direction of the magnetic element 30 changes, and the output voltage or output current from the magnetic element 30 changes. The greater the intensity of the light irradiated to the magnetic element 30, the greater the tilt of the magnetization M31 of the first ferromagnetic layer 31 from the initial state. As shown in FIG. 9, the resistance value in the stacking direction of the magnetic element 30 changes, for example, to a second resistance value R2, a third resistance value R3, and a fourth resistance value R4, depending on the tilt of the magnetization M31 of the first ferromagnetic layer 31. Accordingly, the output voltage or output current from the magnetic element 30 changes, for example, to a second value, a third value, and a fourth value.

As the intensity of the light irradiated to the magnetic element 30 increases, the resistance increases in the order of the first resistance value R1, the second resistance value R2, the third resistance value R3, and the fourth resistance value R4. When the power supply PS is a constant current source, the output voltage from the magnetic element 30 increases in the order of the first value, the second value, the third value, and the fourth value. When the power supply PS is a constant voltage source, the output current from the magnetic element 30 decreases in the order of the first value, the second value, the third value, and the fourth value.

Since a spin transfer torque acts on the magnetization M31 of the first ferromagnetic layer 31 in the same direction as the magnetization M32 of the second ferromagnetic layer 32, when the intensity of the light irradiated to the first ferromagnetic layer 31 returns to the first intensity, the magnetization M31 of the first ferromagnetic layer 31 returns to its initial state. At this time, the resistance value in the stacking direction of the magnetic element 30 returns to the first resistance value R1, and the output voltage or output current from the magnetic element 30 returns to the first value.

Here, as an example, the case where the magnetization M31 and the magnetization M32 are parallel in the initial state has been described hereinbefore, but the magnetization M31 and the magnetization M32 may be antiparallel (in a state where the magnetizations are oriented in opposite directions) in the initial state. In this case, the resistance value in the stacking direction of the magnetic element 30 decreases as the inclination of the magnetization M31 increases with respect to the initial state. When the initial state is a state in which the magnetization M31 and the magnetization M32 are antiparallel, it is advantageous to pass the sense current from the second ferromagnetic layer 32 to the first ferromagnetic layer 31. By passing the sense current from the second ferromagnetic layer 32 to the first ferromagnetic layer 31, a spin transfer torque in the opposite direction to the magnetization M32 of the second ferromagnetic layer 32 acts on the magnetization M31 of the first ferromagnetic layer 31. As a result, the magnetizations M31 and M32 are antiparallel to each other in the initial state.

With reference to FIG. 10, the second mechanism of operation of the magnetic element 30 of the optical device 1A in the first embodiment will be described hereinafter.

The initial state shown in FIG. 10 is similar to the initial state shown in FIG. 9. In the example shown in FIG. 10, it is also advantageous to pass a constant current (sense current) from the first ferromagnetic layer 31 to the second ferromagnetic layer 32. By passing the sense current from the first ferromagnetic layer 31 to the second ferromagnetic layer 32, a spin transfer torque in the same direction as the magnetization M32 of the second ferromagnetic layer 32 acts on the magnetization M31 of the first ferromagnetic layer 31, and the initial state is maintained.

When the intensity of the light irradiated to the magnetic element 30 changes, the external energy applied to the first ferromagnetic layer 31 changes. As a result, the magnitude of the magnetization M31 of the first ferromagnetic layer 31 becomes smaller than the initial state.

When the magnetization M31 of the first ferromagnetic layer 31 becomes smaller from the initial state, the resistance value of the magnetic element 30 in the stacking direction changes, and the output voltage or output current from the magnetic element 30 changes. The greater the intensity of the light irradiated to the magnetic element 30, the smaller the magnitude of the magnetization M31 of the first ferromagnetic layer 31 becomes compared to the initial state. As shown in FIG. 10, the resistance value of the magnetic element 30 in the stacking direction changes, for example, to the second resistance value R2, the third resistance value R3, and the fourth resistance value R4, depending on the magnitude of the magnetization M31 of the first ferromagnetic layer 31. Accordingly, the output voltage or output current from the magnetic element 30 changes, for example, to the second value, the third value, and the fourth value.

As the intensity of the light irradiated to the magnetic element 30 increases, the resistance increases in the order of the first resistance value R1, the second resistance value R2, the third resistance value R3, and the fourth resistance value R4. When the power supply PS is a constant current source, the output voltage from the magnetic element 30 increases in the order of the first value, the second value, the third value, and the fourth value. When the power supply PS is a constant voltage source, the output current from the magnetic element 30 decreases in the order of the first value, the second value, the third value, and the fourth value.

When the intensity of the light irradiated to the first ferromagnetic layer 31 returns to the first intensity, the magnetization M31 of the first ferromagnetic layer 31 returns to the initial state. At this time, the resistance value in the stacking direction of the magnetic element 30 returns to the first resistance value R1, and the output voltage or output current from the magnetic element 30 returns to the first value.

In FIG. 10 as well, the magnetization M31 and the magnetization M32 may be antiparallel in the initial state. In this case, the smaller the magnitude of the magnetization M31 is relative to the initial state, the smaller the resistance value in the stacking direction of the magnetic element 30 becomes. When the magnetization M31 and the magnetization M32 are in an antiparallel state in the initial state, it is advantageous to pass the sense current from the second ferromagnetic layer 32 toward the first ferromagnetic layer 31.

In both the principles of the first mechanism shown in FIG. 9 and the second mechanism shown in FIG. 10, the electric signal output from the magnetic element 30 changes depending on the intensity of the light irradiated to the magnetic element 30. The magnetic element 30 functions as an optical sensor that detects changes in the state of the irradiated light and outputs an electric signal in response to the intensity of the light.

### Second Embodiment

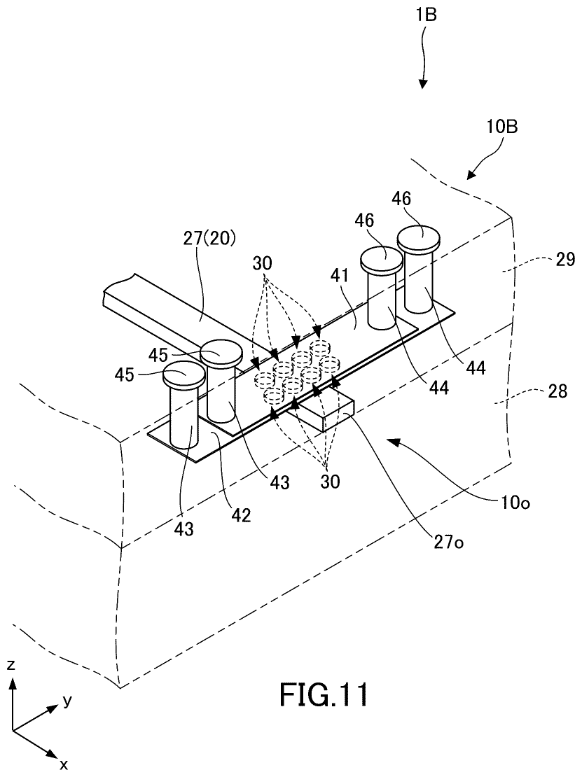

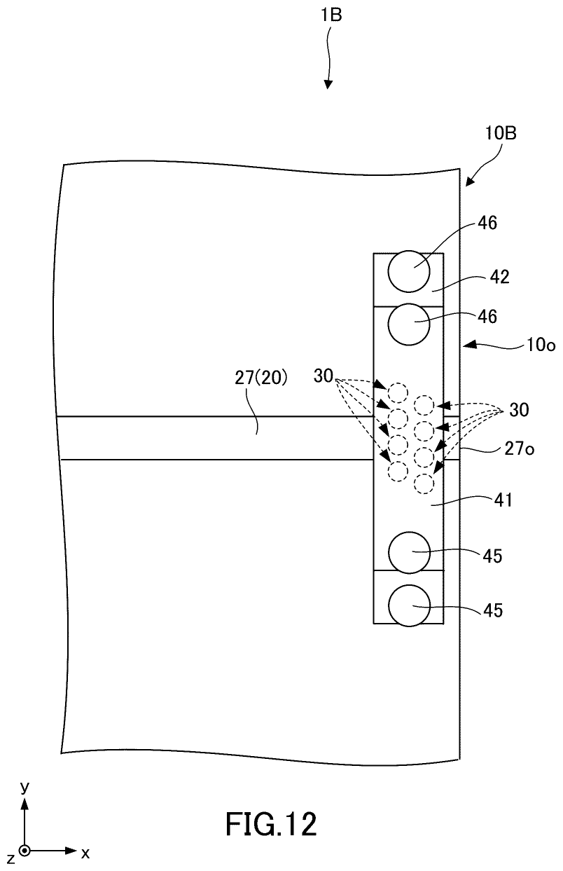

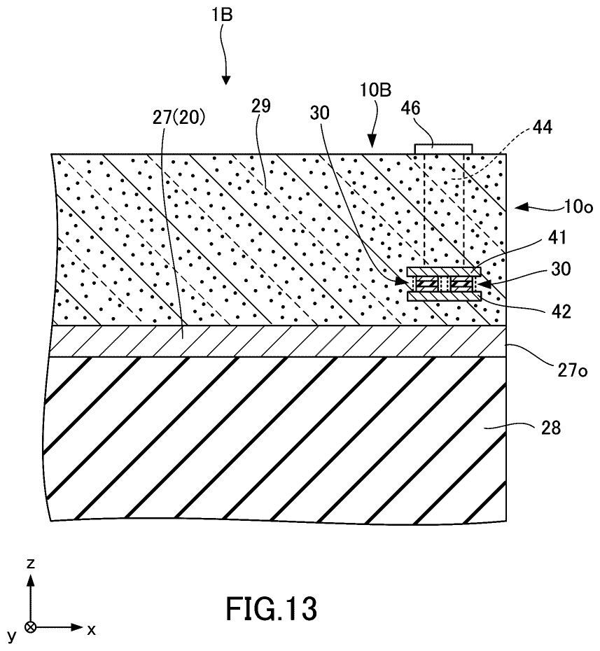

A second embodiment of the present disclosure will be described hereinafter. FIG. 11 is a perspective view showing the vicinity of the magnetic element 30 of the optical device 1B in the second embodiment. FIG. 12 is a plan view showing the vicinity of the magnetic element 30 in FIG. 11. FIG. 13 is a cross-sectional view showing the vicinity of the magnetic element 30 in FIG. 11. The cross section shown in FIG. 13 is a cross section of the magnetic element 30 in the zx plane, and corresponds to the cross section along the line B-B shown in FIG. 1. In the second embodiment, the same components as those in the first embodiment are given the same reference numerals, and thus the description is omitted as appropriate.

As shown in FIG. 11 to FIG. 13, the optical device 1B in the second embodiment has a plurality of magnetic elements 30. The plurality of magnetic elements 30 are arranged in the vicinity of the optical output port 27o. The plurality of magnetic elements 30 are arranged so as to be embedded in the clad 29 of the optical waveguide element 10B, for example. The plurality of magnetic elements 30 are electrically connected to the upper electrode 41 and the lower electrode 42, and each magnetic element 30 functions as an optical sensor that detects the reflected light LR.

According to the second embodiment, the irradiation area of the reflected light LR can be increased by arranging the plurality of magnetic elements 30, and the SN ratio (signal-to-noise ratio) can be improved to enhance the detection accuracy. Furthermore, the arrangement of multiple magnetic elements 30 ensures redundancy, and the reliability and availability of the reflected light LR detection can be ensured.

In the example shown in FIG. 11 to FIG. 13, eight magnetic elements 30 are arranged in an array in the vicinity of the optical output port 27o. More specifically, four magnetic elements 30 are arranged in two rows, with the magnetic elements 30 in adjacent rows being arranged in a staggered pattern. This makes it possible to efficiently increase the area over which the reflected light LR that has entered the clad 29 from the optical output surface 10o is irradiated onto the multiple magnetic elements 30.

### Third Embodiment

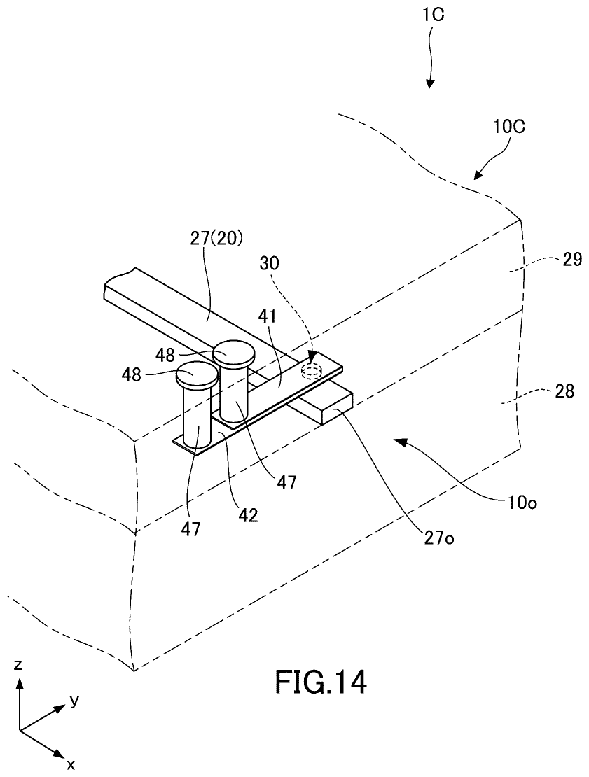

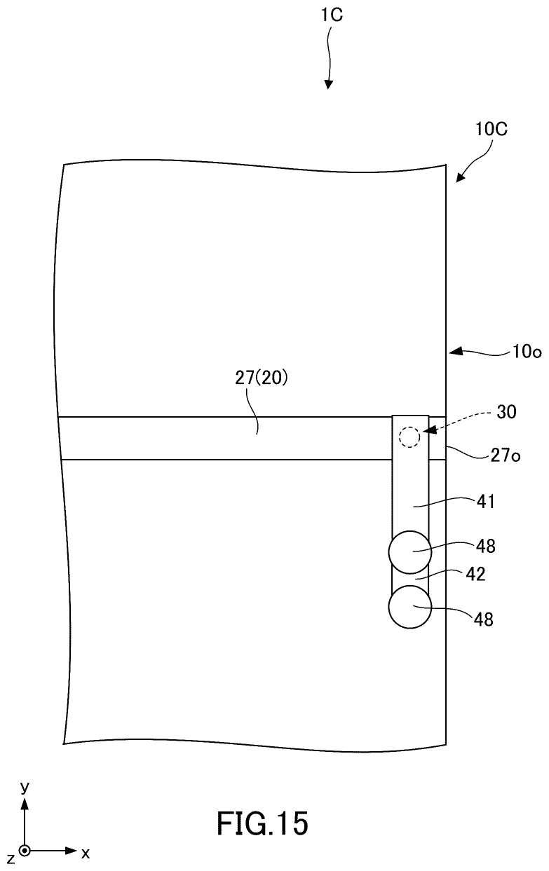

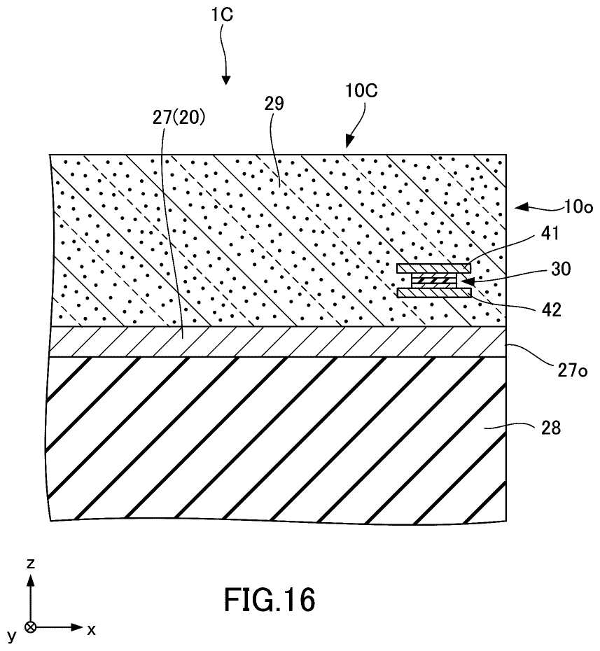

A third embodiment of the present disclosure will be described hereinafter. FIG. 14 is a perspective view showing the vicinity of the magnetic element 30 of the optical device 1C in the third embodiment. FIG. 15 is a plan view showing the vicinity of the magnetic element 30 in FIG. 14. FIG. 16 is a cross-sectional view showing the vicinity of the magnetic element 30 in FIG. 14. The cross section shown in FIG. 16 is a cross section of the magnetic element 30 in the zx plane, and corresponds to the cross section along the line B-B in FIG. 1. In the third embodiment, the same components as those in the first embodiment are given the same reference numerals, and the description will be omitted as appropriate.

The optical device 1C in the third embodiment has a magnetic element 30. The magnetic element 30 is disposed in the vicinity of the optical output port 27o. The magnetic element 30 is disposed so as to be embedded in the clad 29 of the optical waveguide element 10C, for example.

As shown in FIG. 14 to FIG. 16, the magnetic element 30 is electrically connected to the upper electrode 41, the lower electrode 42, the via wiring 47, and the input/output terminal 48. The optical device 1C in the third embodiment differs from the optical device 1A in the first embodiment in that the input terminal 45 and the output terminal 46 are a common input/output terminal 48.

The via wiring 47 connects the input/output terminal 48 to the upper electrode 41 or the lower electrode 42. The input/output terminal 48 is provided corresponding to the via wiring 47. Here, as an example, two via wirings 47 and two input/output terminals 48 are provided. One of the input/output terminals 48 is electrically connected to the upper electrode 41, and a current or voltage is input and an electrical signal is output. The other of the input/output terminals 48 is electrically connected to the lower electrode 42 and is connected to a reference potential. The input/output terminals 48 are exposed on the upper surface of the clad 29, for example.

According to the third embodiment, the number of terminals can be reduced by using a common input/output terminal 48 to input a current or voltage and output an electrical signal. This allows the optical device 1C to be further miniaturized, and creates space on the substrate 28 for arranging other components, thereby making it possible to improve the degree of freedom in design.

### Fourth Embodiment

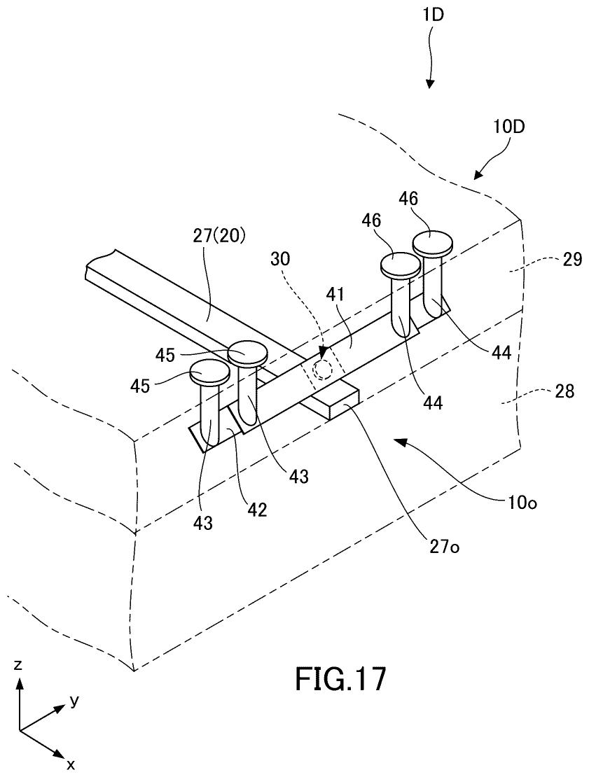

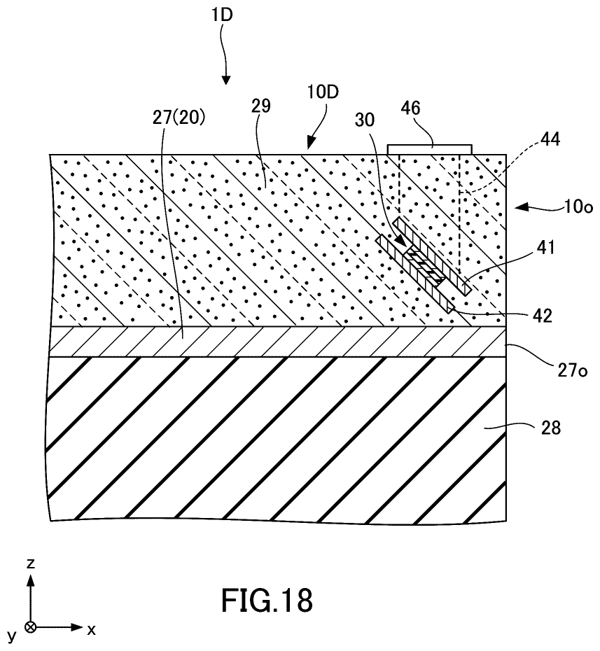

A fourth embodiment of the present disclosure will be described hereinafter. FIG. 17 is a perspective view showing the vicinity of the magnetic element 30 of the optical device 1D in the fourth embodiment. FIG. 18 is a cross-sectional view showing the vicinity of the magnetic element 30 in FIG. 17. The cross-section shown in FIG. 18 is a cross-section of the magnetic element 30 in the zx plane, and corresponds to the cross-section along line B-B in FIG. 1. In the fourth embodiment, the same components as those in the first embodiment are given the same reference numerals, and the description will be omitted as appropriate.

As shown in FIG. 17 and FIG. 18, the optical device 1D in the fourth embodiment differs from the optical device 1A in the first embodiment in that the stacking direction of the magnetic element 30 is inclined with respect to the z direction.

The optical device 1D in the fourth embodiment has a magnetic element 30. The magnetic element 30 is disposed in the vicinity of the optical output port 27o and is disposed so as to be embedded in the clad 29 of the optical waveguide element 10D.

The stacking direction of the magnetic element 30 may be disposed so as to be inclined with respect to the z direction. At least a part of the reflected light LR is irradiated to the magnetic element 30 from a direction intersecting the stacking direction of the magnetic element 30. However, while in the first embodiment described above, at least a part of the reflected light LR is irradiated to the magnetic element 30 from a direction perpendicular to the stacking direction, in the fourth embodiment, at least a part of the reflected light LR is irradiated to the magnetic element 30 from an oblique direction (non-perpendicular direction) with respect to the stacking direction. The angle between the stacking direction of the magnetic element 30 and the z direction is not particularly limited, but can be set to, for example, 45°.

In FIG. 17 and FIG. 18, the upper surface of the magnetic element 30 is arranged so as to face the optical output surface 10o side, which is the direction of arrival of the reflected light LR. In this case, it is advantageous to use a material that is optically transparent in the wavelength range of the reflected light LR as the material of the upper electrode 41. The lower surface of the magnetic element 30 may be arranged so as to face the optical output surface 10o side. In this case, it is advantageous to use a material that is optically transparent in the wavelength range of the reflected light LR as the material of the lower electrode 42.

According to the fourth embodiment, by arranging the magnetic element 30 at an oblique angle, it is possible to increase the light receiving area of the reflected light LR with respect to the magnetic element 30. This makes it possible to increase the interaction between the magnetic element 30 and the reflected light LR, and thereby improve the detection accuracy of the reflected light LR.

### Fifth Embodiment

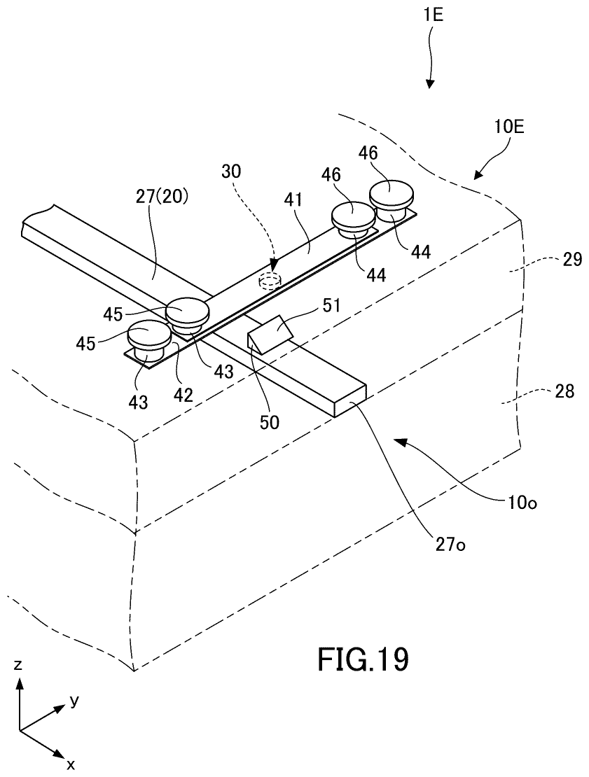

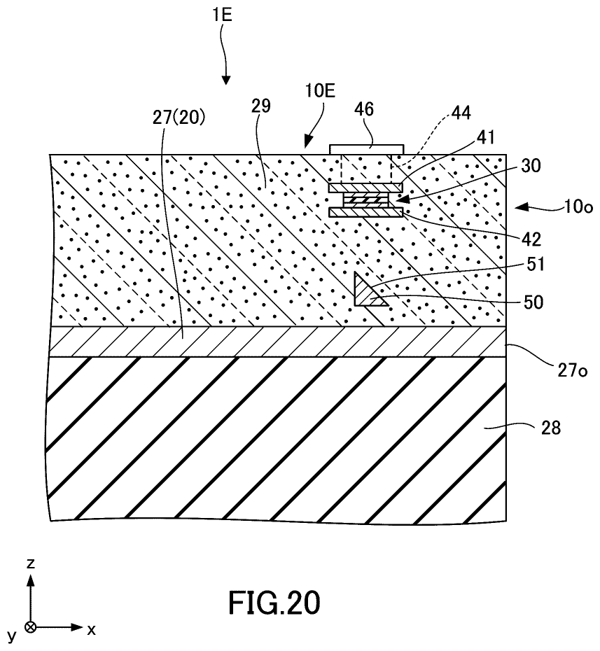

A fifth embodiment of the present disclosure will be described hereinafter. FIG. 19 is a perspective view showing the vicinity of the magnetic element 30 of the optical device 1E in the fifth embodiment. FIG. 20 is a cross-sectional view showing the vicinity of the magnetic element 30 in FIG. 19. The cross section shown in FIG. 20 is a cross section of the magnetic element 30 in the zx plane, and corresponds to the cross section along the line B-B in FIG. 1. In the fifth embodiment, the same components as those in the first embodiment are given the same reference numerals, and the description is omitted as appropriate.

As shown in FIG. 19 and FIG. 20, the optical device 1E in the fifth embodiment differs from the optical device 1A in the first embodiment in that the optical device 1E includes a reflector 50.

The optical device 1E in the fifth embodiment has a magnetic element 30. The magnetic element 30 is disposed in the vicinity of the optical output port 27o. The magnetic element 30 is disposed, for example, so as to be embedded in the clad 29 of the optical waveguide element 10E.

The reflector 50 is disposed in the vicinity of the optical output port 27o so as to be embedded in the clad 29. The reflected light LR irradiated to the optical output surface 10o propagates while being diffused in the clad 29. The reflector 50 reflects a part of the reflected light LR to change its traveling direction. For example, a reflecting mirror can be used as the reflector 50. The reflecting mirror has an inclined surface 51 that reflects light. In the example shown in FIG. 19 and FIG. 20, the reflector 50 changes (reflects) the traveling direction of the reflected light LR propagating in the clad 29 in the negative x direction to the positive z direction. The normal of the inclined surface 51 forms an angle of 45° with respect to the x direction and the z direction, for example.

The magnetic element 30 is disposed at a position where the light from the reflector 50 is irradiated. In the example shown in FIG. 19 and FIG. 20, the magnetic element 30 is disposed above the reflector 50. The traveling direction of at least a part of the reflected light LR is changed by the reflector 50, and the magnetic element 30 is irradiated from the stacking direction of the magnetic element 30.

In FIG. 19 and FIG. 20, the lower surface of the magnetic element 30 is arranged so as to face the reflector 50. In this case, it is advantageous to use a material that is optically transparent in the wavelength range of the reflected light LR as the material of the lower electrode 42. The upper surface of the magnetic element 30 may be arranged so as to face the reflector 50. In this case, it is advantageous to use a material that is optically transparent in the wavelength range of the reflected light LR as the material of the lower electrode 42. The stacking direction of the magnetic element 30 may be inclined with respect to the z direction, and the side surface of the magnetic element 30 may be arranged so as to face the reflector 50.

According to the fifth embodiment, the traveling direction of the reflected light LR propagating in the clad 29 is changed by the reflector 50, thereby improving the irradiation efficiency of the reflected light LR to the magnetic element 30. In addition, the arrangement position of the magnetic element 30 can be flexibly set, thereby improving the degree of freedom in design.

### Sixth Embodiment

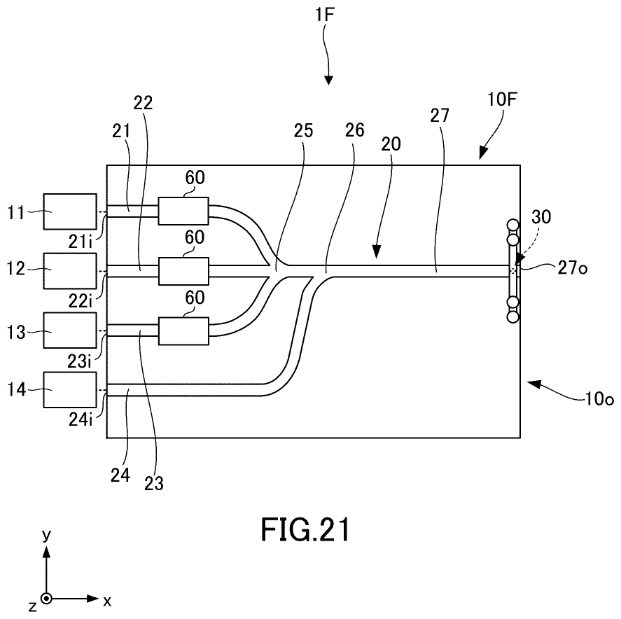

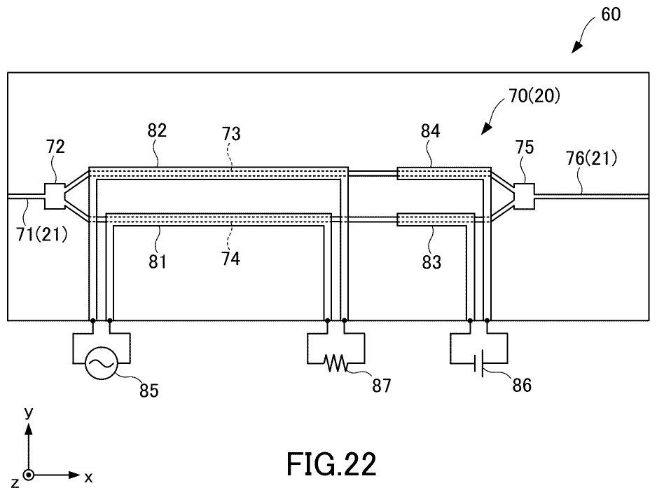

The sixth embodiment of the present disclosure will be described hereinafter. FIG. 21 is a schematic plan view of an optical device 1F in the sixth embodiment. FIG. 22 is a schematic plan view of the optical modulation section 60 in FIG. 21. In the sixth embodiment, the same components as those in the first embodiment are given the same reference numerals, and the description will be omitted as appropriate.

As shown in FIG. 21, the optical waveguide element 10F of the optical device 1F includes an optical modulation section 60 that modulates the intensity of the visible light of each color emitted by the laser diodes 11, 12, and 13. The laser diodes 11, 12, and 13 can be ones that emit laser light of a constant intensity. The optical modulation section 60 is provided, for example, in each of the input waveguides 21, 22, and 23, and can independently modulate the visible light of each color.

In the optical modulation section 60, a Mach-Zehnder type waveguide 70 having a Mach-Zehnder interferometer structure is formed as the waveguide 20. It is advantageous to use a material having an electro-optic effect as the material of the Mach-Zehnder type waveguide 70, and for example, it is advantageous to use a material containing lithium niobate as the main component.

The optical modulation section 60 shown in FIG. 22 will be described hereinafter. FIG. 22 illustrates the optical modulation section 60 provided in a part of the input waveguide 21, but the optical modulation section 60 provided in the input waveguides 22 and 23 also has the same configuration. The optical modulation section 60 shown in FIG. 22 is an example, and is not limited to this configuration.

The optical modulation section 60 shown in FIG. 22 includes an upstream waveguide 71, a branching section 72, a first waveguide 73 and a second waveguide 74, a multiplexing section 75, and a downstream waveguide 76. The upstream waveguide 71 constitutes a portion close to the optical input port 21i of the input waveguide 21. The downstream waveguide 76 constitutes a portion close to the first multiplexing section 25 of the input waveguide 21.

The upstream waveguide 71 branches into a first waveguide 73 and a second waveguide 74 at the branching section 72. The first waveguide 73 and the second waveguide 74 extend parallel to each other and merge into the downstream waveguide 76 at the multiplexing section 75.

The optical modulation section 60 further includes electrodes 81, 82, 83, and 84 that apply an electric field to the Mach-Zehnder type waveguide 70, power sources 85 and 86, and a termination resistor 87. The power source 85 applies a modulation voltage to the Mach-Zehnder type waveguide 70 through the electrodes 81 and 82. The power supply 86 applies a DC bias voltage to the Mach-Zehnder type waveguide 70 through the electrodes 83 and 84.

When performing optical modulation, a voltage is applied between the electrodes 81 and 82. This applies an electric field to the first and second waveguides 73 and 74, and the refractive indexes of the first and second waveguides 73 and 74 change due to the electro-optic effect. The visible light emitted by the laser diode 11 propagates through the upstream waveguide 71 and is split by the branching section 72, and then propagates through the first and second waveguides 73 and 74. When a refractive index difference is generated between the first and second waveguides 73 and 74, a phase difference occurs between the light propagating through the first and second waveguides 73 and 74. By controlling this phase difference, the intensity of the light multiplexed in the multiplexing section 75 can be controlled to a desired value.

According to the sixth embodiment, the optical modulation section 60 mounted on the optical waveguide element 10F can perform optical modulation, thereby making it possible to realize excellent responsiveness while suppressing power consumption as compared to controlling the intensity of the emitted light from the laser diodes 11, 12, and 13.

### [Optical System]

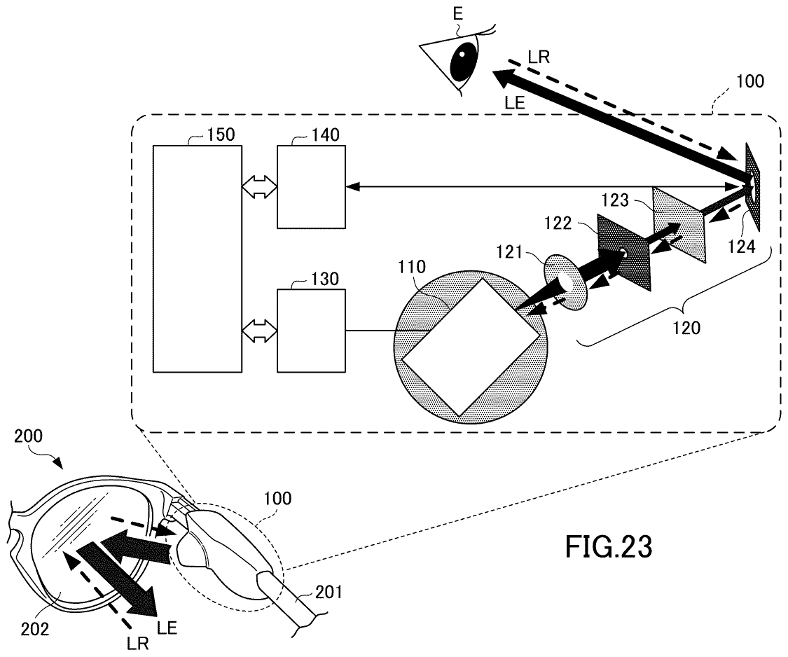

The optical system according to the present disclosure will be described. FIG. 23 is a conceptual diagram of an optical system 100 according to the present disclosure. FIG. 23 illustrates an optical system 100 equipped with the optical device 1A in the first embodiment, but the optical devices 1B to 1F in the second to sixth embodiments may also be used.

The present disclosure can provide an optical system 100 equipped with the optical devices 1A to 1F in the first to sixth embodiments described above. The optical system 100 constitutes, for example, an image display device that displays information that can be visually recognized as an image (still image and moving image). The optical system 100 can be mounted, for example, on a glasses-type terminal such as XR glasses 200.

The XR glasses 200 shown in FIG. 23 have a light source module 110, an optical assembly 120, a laser driver 130, an optical scanning mirror driver 140, and a video controller 150 that controls these drivers.

The XR glasses 200 can be equipped with the optical devices 1A to 1F in the first to sixth embodiments described above as the light source module 110. The light source module 110 is installed, for example, on the frame 201 of the XR glasses 200.

The optical assembly 120 optically processes the output light LE emitted by the light source module 110. For example, the optical assembly 120 has a collimator lens 121, a slit 122, an ND filter 123, and an optical scanning mirror 124. The optical assembly 120 shown in FIG. 23 is an example, and other configurations may be used.

The optical scanning mirror 124 can be, for example, a MEMS mirror. In order to project a two-dimensional image, it is advantageous to use a two-axis MEMS mirror that vibrates to reflect the laser light by changing the angle in the horizontal and vertical directions as the optical scanning mirror 124.

In the XR glasses 200 shown in FIG. 23, the light source module 110 attached to the frame 201 emits the emitted light LE. The emitted light LE is reflected by the optical scanning mirror 124 and further reflected by the lens 202 of the XR glasses 200. The light reflected by the lens 202 is incident on the human eye (eyeball) and forms an image on the retina M, allowing the user to visually recognize it as an image.

The XR glasses 200 shown in FIG. 23 have an eye tracking function. Near-infrared light emitted by the laser diode 14 is used for eye tracking. The near-infrared light emitted by the laser diode 14 is reflected by the human eyeball. Parts of the eyeball that reflect the light include, for example, the cornea, pupil, iris, retina, and sclera. The reflected light LR reflected by the eyeball travels in the opposite direction along the same optical path as the emitted light LE and reaches the light source module 110.

The reflected light LR is irradiated onto the optical output surface 10o of the optical devices 1A to 1F constituting the light source module 110. A part of the reflected light LR irradiated onto the optical output surface 10o propagates through the clad 29 and is irradiated onto the magnetic element 30. The magnetic element 30 outputs an electrical signal in response to the intensity of the reflected light LR. The XR glasses 200 can identify the movement of the gaze position (point of gaze) based on the irradiation position of the near-infrared light adjusted by the optical scanning mirror 124 and the intensity of the reflected light LR.

### Derivation Example

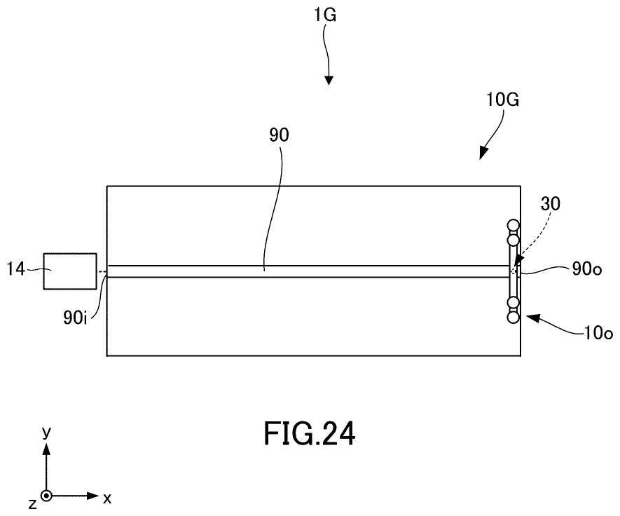

FIG. 24 is a schematic plan view of an optical device 1G in a derivative example of the present disclosure. The optical devices 1A to 1F described above are configured to emit both visible light and near-infrared light, but the optical device 1G is configured to emit only near-infrared light.

The optical device 1G shown in FIG. 24 has a laser diode 14, an optical waveguide element 10G, and a magnetic element 30. The optical waveguide element 10G has a waveguide 90 for propagating light. An optical input port 90i is formed at one end of the waveguide 90. An optical output port 90o is formed at the other end of the waveguide 90. The waveguide 90 corresponds to the above-mentioned waveguide 20. The optical input port 90i and the optical output port 90o correspond to the above-mentioned optical input port 24i and the optical output port 27o, respectively.

The laser diode 14 emits near-infrared light. The laser light emitted by the laser diode 14 is incident on the optical input port 90i of the waveguide 90 and is emitted as emitted light LE from the optical output port 90o. The emitted light LE is irradiated to the irradiated object E. The reflected light LR reflected by the irradiated object E travels in the opposite direction along the same optical path as the emitted light LE, and is irradiated onto the optical output surface 10o of the optical waveguide element 10G.

In the optical device 1G, the magnetic element 30 is also disposed in the vicinity of the optical output port 90o. The magnetic element 30 is disposed, for example, so as to be embedded in the clad 29 of the optical waveguide element 10G.

In the optical device 1G shown in FIG. 24, the configuration of the magnetic element 30 and its vicinity is the same as that of the optical device 1A in the first embodiment described above. However, it may be the same as that of the second to fifth embodiments described above.

The reflected light LR irradiated onto the optical output surface 10o propagates through the clad 29 and is irradiated onto the magnetic element 30. The magnetic element 30 outputs an electrical signal in response to the intensity of the irradiated reflected light LR, thereby making it possible to measure the intensity of the reflected light LR.

In this way, according to a derivative example of the present disclosure, it is possible to provide an optical device 1G for eye tracking applications that emits near-infrared light as emitted light LE and measures the intensity of the reflected light LR. Furthermore, according to a derivative example of the present disclosure, it is also possible to provide an optical system for eye tracking applications that includes the optical device 1G.

As described above, the present disclosure has the effect of eliminating the need for highly accurate optical axis adjustment and of being able to properly irradiate reflected light from an irradiated object onto a magnetic element with a simple configuration, and is useful in light detection technology in general. In particular, the present disclosure has the effect of properly irradiating reflected light from the human eyeball onto a magnetic element, and is useful in eye tracking technology in general.

Although the disclosure has been described with respect to only a limited number of embodiments, those skilled in the art, having benefit of this disclosure, will appreciate that various other embodiments may be devised without departing from the spirit and scope of the present disclosure. Accordingly, the technical scope of the disclosed subject matter should be limited only by the attached claims.

### DESCRIPTION OF REFERENCE NUMERALS AND SIGNS

1A, 1B, 1C, 1D, 1E, 1F, 1G Optical device
10A, 10B, 10C, 10D, 10E, 10F, 10G Optical waveguide element
10o Optical output surface
11, 12, 13, 14 Laser diode
20, 90 Waveguide
21, 22, 23, 24 Input waveguide
21i, 22i, 23i, 24i, 90i Optical input port
25 First multiplexing section
26 Second multiplexing section
27 Output waveguide
27o, 90o Optical output port
28 Substrate
29 Clad
30 Magnetic element
31 First ferromagnetic layer
32 Second ferromagnetic layer
33 Spacer layer
34 Third ferromagnetic layer
35 Magnetic coupling layer
36 Underlayer
37 Perpendicular magnetization inducing layer
38 Cap layer
39 Sidewall insulating layer
41 Upper electrode
42 Lower electrode
43, 44, 47 Via wiring
45 Input terminal
46 Output terminal
48 Input/output terminal
50 Reflector
51 Inclined surface
60 Optical modulation section
70 Mach-Zehnder type waveguide
71 Upstream waveguide
72 Branching section
73 First waveguide
74 Second waveguide
75 Multiplexing section
76 Downstream Waveguide
81, 82, 83, 84, Electrode
85, 86 Power supply
87 Termination resistor
100 Optical system
110 Light source module
120 Optical assembly
121 Collimator lens
122 Slit
123 ND filter
124 Optical scanning mirror
130 Laser driver
140 Optical scanning mirror driver
150 Video controller
200 XR glasses
201 Frame
202 Lens
E Irradiated object
G Ground
LE Emitted light
LR Reflected light
M31, M32, M34 Magnetization
PG Reference potential terminal

What is claimed is:

1. An optical device comprising:
at least one magnetic element having a first ferromagnetic layer, a second ferromagnetic layer, and a spacer layer sandwiched between the first ferromagnetic layer and the second ferromagnetic layer;
a laser diode that emits laser light; and
a waveguide,
wherein
the waveguide has at least one optical input port through which the laser light of the laser diode is incident and an optical output port through which the laser light is emitted to the outside, and
the at least one magnetic element is disposed in the vicinity of the optical output port.

2. The optical device according to claim 1, wherein at least a portion of reflected light of the laser light emitted from the optical output port is irradiated onto the at least one magnetic element.

3. The optical device according to claim 2, wherein the at least one magnetic element is disposed at a position that receives the reflected light propagating outside the waveguide.

4. The optical device according to claim 1, further comprising a substrate, the waveguide being formed on the substrate.

5. The optical device according to claim 4, wherein the substrate comprises aluminum oxide.

6. The optical device according to claim 4, wherein the waveguide is formed in a layer comprising lithium niobate arranged on the substrate.

7. The optical device according to claim 4, further comprising a clad covering the waveguide.

8. The optical device according to claim 7, wherein the at least one magnetic element is arranged in the clad.

9. The optical device according to claim 1, further comprising a reflector arranged in the vicinity of the optical output port.

10. The optical device according to claim 9, wherein a lower surface or an upper surface of the at least one magnetic element is arranged to face the reflector.

11. The optical device according to claim 1, wherein the laser diode emits near-infrared light as the laser light.

12. The optical device according to claim 11, comprising a plurality of laser diodes that emit visible light, and an optical modulation section that modulates the intensity of the visible light emitted by each of the plurality of laser diodes.

13. The optical device according to claim 12, wherein the optical modulation section comprises a Mach-Zehnder type waveguide for modulating the visible light emitted by each of the plurality of laser diodes.

14. The optical device according to claim 1, comprising a plurality of said magnetic elements, wherein the plurality of magnetic elements are arranged in an array.

15. The optical device according to claim 14, wherein the plurality of magnetic elements are arranged in a staggered pattern.

16. The optical device according to claim 2, wherein at least a portion of the reflected light is irradiated onto the at least one magnetic element in a direction intersecting the stacking direction of the magnetic element.

17. The optical device according to claim 16, wherein the direction intersecting the stacking direction of the magnetic element is perpendicular to the stacking direction.

18. The optical device according to claim 1, wherein the distance between the at least one magnetic element and the optical output port is equal to or less than 10 wavelengths of the laser light emitted from the laser diode.

19. The optical device according to claim 2, wherein the distance between the at least one magnetic element and the optical output port is set such that the at least one magnetic element is irradiated with 10% or more of the light energy of the reflected light incident on an optical output surface on which the optical output port is formed.

20. An optical system comprising the optical device according to claim 1, and an optical assembly that guides the laser light emitted by the optical device to an irradiated object.
